(19) United States
(12) Patent Application Publication
(10) Pub. No.: US 2025/0372460 A1
(43) Pub. Date: Dec. 4, 2025

(54) SUBSTRATE PROCESSING METHOD, SUBSTRATE PROCESSING APPARATUS, COMPUTER PROGRAM, AND STORAGE MEDIUM

(71) Applicant: SCREEN Holdings Co., Ltd., Kyoto (JP)

(72) Inventors: Hiroakira MATSUI, Kyoto (JP); Shinji SUGIOKA, Kyoto (JP); Harumasa NAKANO, Kyoto (JP)

(21) Appl. No.: 19/214,451

(22) Filed: May 21, 2025

(30) Foreign Application Priority Data
May 29, 2024 (JP) 2024-087433

(51) Int. Cl. H01L 21/66; H01L 21/306

(52) U.S. Cl. CPC H01L 22/20; H01L 21/30604

(57) ABSTRACT

A substrate processing method processes substrates by immersing a substrate in a processing liquid for each lot in a processing tank. The method includes acquiring number-of-substrates information indicating the number of the substrates included in the lot, selecting relationship information in accordance with the number of the substrates from a plurality of items of relationship information, each of which indicates a relationship between the number of the substrates and a correction value of a processing time, acquiring a correction value in accordance with the number of the substrates from the selected relationship information, correcting a processing time based on the acquired correction value such that the processing time is shorter than a processing time adopted in a case where the number of the substrates in the lot is a maximum number, and processing the substrate with the processing liquid in the processing tank based on the corrected processing time.

### CROSS REFERENCE TO RELATED APPLICATIONS

This application claims the benefit of priority to Japanese Patent Application No. 2024-087433 filed on May 29, 2024 and the entire contents of this application are hereby incorporated herein by reference.

### BACKGROUND OF THE INVENTION

### 1. Field of the Invention

The present invention relates to a substrate processing method, a substrate processing apparatus, a computer program, and a storage medium.

### 2. Description of the Related Art

A substrate processing apparatus described in Japanese Patent Application Publication No. 2004-296506 performs etching processing by collectively immersing a plurality of substrates in a heated phosphoric acid solution. The substrate processing apparatus counts the number of substrates collectively processed by a substrate counting mechanism and a substrate counter. The processing time determination portion determines a processing time in accordance with the counted number of substrates with reference to a relationship between the number of substrates and a processing time stored in advance in a storage portion.

### SUMMARY OF THE INVENTION

However, in the substrate processing apparatus described in Japanese Patent Application Publication No. 2004-296506, with five substrates as one unit, a correction amount of the processing time linearly increases from a minimum unit (one to five substrates) to a maximum unit (46 to 50 substrates) of the number of substrates.

The inventors of the present application have made close studies and have achieved novel findings that, in a case where the correction amount of the processing time linearly increases from the minimum number of substrates to the maximum number, an etching amount of the substrates may vary depending on the number of substrates. For example, in a case where micro-etching needs to be performed on substrates, a substrate having an excessive etching amount may have to be discarded if the excessive etching amount is extremely minute.

A preferred embodiment of the present invention provides a substrate processing method, a substrate processing apparatus, a computer program, and a storage medium capable of accurately processing substrates in accordance with the number of substrates.

According to one aspect of the present invention, a substrate processing method processes substrates by immersing at least one substrate in a processing liquid for each lot in a processing tank that stores the processing liquid. The substrate processing method includes acquiring number-of-substrates information indicating the number of the substrates included in the lot, selecting relationship information in accordance with the number of the substrates indicated by the number-of-substrates information from a plurality of items of relationship information, each of which indicates a relationship between the number of the substrates and a correction value of a processing time of the substrates, acquiring a correction value in accordance with the number of the substrates indicated by the number-of-substrates information from the selected relationship information, correcting a processing time of the substrates based on the acquired correction value such that the processing time is shorter than a processing time adopted in a case where the number of the substrates in the lot is a maximum number, and processing the substrate with the processing liquid in the processing tank based on the corrected processing time of the substrates.

According to a mode of the present invention, in the substrate processing method, preferably, each of the plurality of items of relationship information is a function indicating a relationship between the number of the substrates and a correction value of the processing time of the substrates.

According to a mode of the present invention, in the substrate processing method, preferably, the plurality of items of relationship information are defined by a plurality of reference points different from each other. Preferably, the substrate processing method further includes receiving an input of a plurality of items of reference point correction value information which respectively determine the plurality of reference points. Preferably, the plurality of items of reference point correction value information indicate respective correction values of processing times of the substrates which determine the corresponding reference points.

According to a mode of the present invention, preferably, the substrate processing method further includes receiving an input of number setting information for setting the number of the plurality of items of relationship information.

According to a mode of the present invention, preferably, the substrate processing method further includes receiving an input of invalid setting information which invalidates a function of correcting the processing time of the substrates.

According to a mode of the present invention, in the substrate processing method, preferably, the plurality of items of relationship information are defined by a plurality of reference points different from each other. Preferably, the substrate processing method further includes receiving an input of a plurality of items of reference point number-of-substrates information which respectively determine the plurality of reference points. Preferably, the plurality of items of reference point number-of-substrates information indicate respective numbers of the substrates in one lot which determine the corresponding reference points.

According to a mode of the present invention, in the substrate processing method, preferably, in a case where the number of the substrates in the lot indicates the maximum number, a correction value of the processing time of the substrates is zero. Preferably, in each of the plurality of items of relationship information, the correction value of the processing time of the substrates increases as the number of the substrates decreases. Preferably, in correcting the processing time, the processing time of the substrates is corrected by subtracting the correction value in accordance with the number of the substrates indicated by the number-of-substrates information from the processing time of the substrates adopted in a case where the number of the substrates in the lot indicates the maximum number.

According to a mode of the present invention, in the substrate processing method, preferably, in acquiring the correction value, the correction value is set in accordance with disposition of the substrates in the processing tank. Preferably, in correcting the processing time, the processing time of the substrates is corrected based on the set correction value.

According to a mode of the present invention, preferably, in the substrate processing method, in acquiring the correction value, in a case where the substrates are disposed in a first disposition state in the processing tank, a correction value of a processing time of the substrates disposed in the first disposition state is set such that a corrected processing time of the substrates is shorter than a corrected processing time of the substrates disposed in a reference disposition state. Preferably, the reference disposition state is a state in which the substrates are continuously disposed at equal intervals in a predetermined direction in the processing tank and are disposed in a region including a central portion of a substrate disposition maximum region in the predetermined direction, and in the state, an interval between the adjacent substrates indicates a first distance. Preferably, the substrate disposition maximum region indicates a region where the substrates are disposed in a case where the number of the substrates in the lot is the maximum number. Preferably, the first disposition state is a state in which the substrates are disposed at equal intervals in the predetermined direction in the processing tank, and an interval between the adjacent substrates indicates a second distance longer than the first distance.

According to a mode of the present invention, preferably, in the substrate processing method, in acquiring the correction value, in a case where the substrates are disposed in a second disposition state in the processing tank, a correction value of a processing time of the substrates disposed in the second disposition state is set such that a corrected processing time of the substrates is longer than a corrected processing time of the substrates disposed in a reference disposition state. Preferably, the reference disposition state is a state in which the substrates are continuously disposed at equal intervals in a predetermined direction in the processing tank and are disposed in a region including a central portion of a substrate disposition maximum region in the predetermined direction, and in the state, an interval between the adjacent substrates indicates a first distance. Preferably, the substrate disposition maximum region indicates a region where the substrates are disposed in a case where the number of the substrates in the lot is the maximum number. Preferably, the second disposition state is a state in which the plurality of substrates in the lot are divided into a first substrate group and a second substrate group and are disposed in the processing tank. Preferably, the first substrate group and the second substrate group are not disposed in a central portion of the substrate disposition maximum region. Preferably, the first substrate group is disposed in an end region on one side of the substrate disposition maximum region in the predetermined direction. Preferably, the second substrate group is disposed in an end region on another side of the substrate disposition maximum region in the predetermined direction. Preferably, in each of the first substrate group and the second substrate group, two or more of the substrates are disposed at equal intervals in the predetermined direction, and an interval between the adjacent substrates indicates the first distance.

According to a mode of the present invention, preferably, in acquiring the correction value, in a case where the substrates are disposed in a third disposition state in the processing tank, a correction value of a processing time of the substrates disposed in the third disposition state is set such that a corrected processing time of the substrates is longer than a corrected processing time of the substrates disposed in a reference disposition state. Preferably, the reference disposition state is a state in which the substrates are continuously disposed at equal intervals in a predetermined direction in the processing tank and are disposed in a region including a central portion of a substrate disposition maximum region in the predetermined direction, and in the state, an interval between the adjacent substrates indicates a first distance. Preferably, the substrate disposition maximum region indicates a region where the substrates are disposed in a case where the number of the substrates in the lot is the maximum number. Preferably, the third disposition state is a state in which the plurality of substrates in the lot are disposed in either a first substrate group or a second substrate group in the processing tank. Preferably, the first substrate group and the second substrate group are not disposed in a central portion of the substrate disposition maximum region. Preferably, the first substrate group is disposed in an end region on the one side of the substrate disposition maximum region in the predetermined direction. Preferably, the second substrate group is disposed in an end region on another side of the substrate disposition maximum region in the predetermined direction. Preferably, in each of the first substrate group and the second substrate group, two or more of the substrates are disposed at equal intervals in the predetermined direction, and an interval between the adjacent substrates indicates the first distance.

According to a mode of the present invention, preferably, in the substrate processing method, the processing time of the substrates before correction is divided into a plurality of step periods. Preferably, in correcting the processing time, of the plurality of step periods, a step period set as a period in which a chemical liquid is replenished is corrected based on the acquired correction value. Preferably, in processing the substrates, the chemical liquid is replenished to the processing tank in the corrected step period.

According to a mode of the present invention, preferably, in the substrate processing method, in correcting the processing time, two or more step periods are corrected by equally distributing or proportionally distributing the acquired correction value to the two or more step periods in which the chemical liquid is replenished.

According to a mode of the present invention, preferably, in the substrate processing method, a plurality of the lots are processed in a plurality of the processing tanks, respectively. Preferably, a plurality of tank-dependent correction values are assigned to the plurality of processing tanks, respectively. Preferably, the tank-dependent correction values indicate correction values for correcting processing times of the substrates in accordance with processing characteristics of the corresponding processing tanks. Preferably, in correcting the processing time, the processing times of the substrates is corrected based on the acquired correction values and the tank-dependent correction values.

According to another aspect of the present invention, a substrate processing apparatus processes at least one substrate with a processing liquid for each lot. The substrate processing apparatus includes a processing tank, a substrate holder, a storage, a selector, a corrector, and an immersion controller. The processing tank stores the processing liquid. The substrate holder holds the substrates and immerses the substrates in the processing liquid. The storage stores number-of-substrates information indicating the number of the substrates included in the lot. The selector selects relationship information in accordance with the number of the substrates indicated by the number-of-substrates information from a plurality of items of relationship information, each of which indicates a relationship between the number of the substrates and a correction value of a processing time of the substrates. The corrector acquires a correction value in accordance with the number of the substrates indicated by the number-of-substrates information from the selected relationship information, and corrects the processing time of the substrates based on the correction value such that the processing time is shorter than a processing time adopted in a case where the number of the substrates in the lot is the maximum number. The immersion controller controls the substrate holder such that the substrates are immersed in the processing liquid in accordance with the corrected processing time of the substrates.

According to still another aspect of the present invention, a computer program causes a computer to execute the substrate processing method. The substrate processing method processes substrates for each lot by immersing the substrates in a processing liquid stored in a processing tank by a substrate holder that holds at least one substrate. The computer program causes the computer to execute computing in accordance with the substrate processing method having the characteristics described above. According to one preferred embodiment, the computer program causes the computer to execute acquiring number-of-substrates information indicating the number of the substrates included in the lot, selecting relationship information in accordance with the number of the substrates indicated by the number-of-substrates information from a plurality of items of relationship information, each of which indicates a relationship between the number of the substrates and a correction value of a processing time of the substrates, acquiring a correction value in accordance with the number of the substrates indicated by the number-of-substrates information from the selected relationship information, correcting a processing time of the substrates based on the acquired correction value such that the processing time is shorter than a processing time in a case where the number of the substrates of the lot is a maximum number, and controlling the substrate holder such that the substrates are immersed in the processing liquid in accordance with the corrected processing time of the substrates. The computer program may be stored (recorded) in a non-transitory computer-readable storage medium (recording medium).

The aforementioned or yet other objects, characteristics, and effects of the present invention will be clarified by the descriptions of preferred embodiments to be described below with reference to accompanying drawings.

### BRIEF DESCRIPTION OF THE DRAWINGS

FIG. 1 is a schematic cross-sectional view showing a substrate processing apparatus according to preferred embodiment 1 of the present invention.

FIG. 2(a) is a perspective view showing a state before a substrate is immersed in a processing liquid according to preferred embodiment 1. FIG. 2(b) is a perspective view showing a state in which the substrate is immersed in the processing liquid according to preferred embodiment 1.

FIG. 3 is a graph showing a relationship between the number of substrates in one lot and an etching rate according to preferred embodiment 1.

FIG. 4 is a diagram showing an example of a plurality of items of relationship information according to preferred embodiment 1.

FIG. 5 is a block diagram showing a controller according to preferred embodiment 1.

FIG. 6(a) is a graph showing a plurality of items of relationship information corresponding to a first example of recipe information according to preferred embodiment 1. FIG. 6(b) is a diagram showing the first example of the recipe information according to preferred embodiment 1.

FIG. 7(a) is a graph showing a plurality of items of relationship information corresponding to a second example of recipe information according to preferred embodiment 1. FIG. 7(b) is a diagram showing the second example of the recipe information according to preferred embodiment 1.

FIG. 8(a) is a graph showing a plurality of items of relationship information corresponding to a third example of recipe information according to preferred embodiment 1. FIG. 8(b) is a diagram showing the third example of the recipe information according to preferred embodiment 1.

FIG. 9(a) is a graph showing a plurality of items of relationship information corresponding to a fourth example of recipe information according to preferred embodiment 1. FIG. 9(b) is a diagram showing the fourth example of the recipe information according to preferred embodiment 1.

FIG. 10(a) is a graph showing a plurality of items of relationship information corresponding to a fifth example of recipe information according to preferred embodiment 1. FIG. 10(b) is a diagram showing the fifth example of the recipe information according to preferred embodiment 1.

FIG. 11 is a flowchart showing a substrate processing method according to preferred embodiment 1.

FIG. 12(a) is a view showing a reference disposition state of substrates according to a first modification example of preferred embodiment 1. FIG. 12(b) is a graph showing a plurality of items of relationship information corresponding to the reference disposition state of the substrates according to the first modification example.

FIG. 13(a) is a view showing a first disposition state of substrates according to the first modification example. FIG. 13(b) is a graph showing a plurality of items of relationship information corresponding to the first disposition state of the substrates according to the first modification example.

FIG. 14(a) is a view showing a second disposition state of substrates according to the first modification example. FIG. 14(b) is a graph showing a plurality of items of relationship information corresponding to the second disposition state of the substrates according to the first modification example.

FIG. 15 is a diagram showing recipe information according to a second modification example of preferred embodiment 1.

FIG. 16 is a flowchart showing the substrate processing method according to a second modification example.

FIG. 17 is a schematic view showing a substrate processing system according to preferred embodiment 2 of the present invention.

FIG. 18 is a diagram showing recipe information according to preferred embodiment 2.

FIG. 19 is a flowchart showing a substrate processing method according to preferred embodiment 2.

### DETAILED DESCRIPTION OF THE EXAMPLE EMBODIMENTS

Preferred embodiments of the present invention shall now be described with reference to the drawings. Here, portions that are the same or are corresponding in the figures shall be denoted by the same reference signs and descriptions shall not be repeated. In addition, in the figures, an X-axis, a Y-axis, and a Z-axis are shown, as appropriate, for ease of understanding. The X-axis, the Y-axis, and the Z-axis are orthogonal to each other, the X-axis and the Y-axis are parallel to a horizontal direction, and the Z-axis is parallel to a vertical direction.

### Preferred Embodiment 1

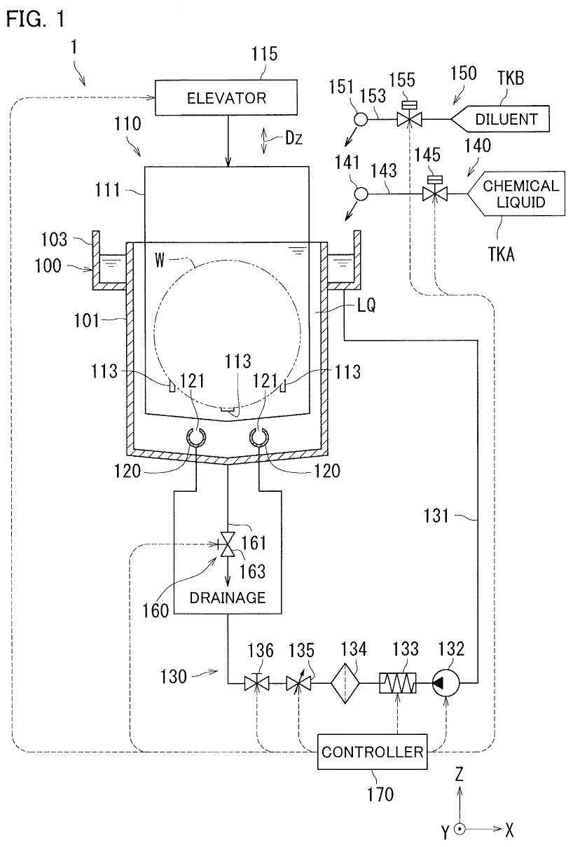

A substrate processing apparatus 1 according to preferred embodiment 1 of the present invention will be described with reference to FIGS. 1 to 11. FIG. 1 is a schematic cross-sectional view showing the substrate processing apparatus 1. The substrate processing apparatus 1 shown in FIG. 1 processes at least one substrate W with a processing liquid LQ for each lot. The substrate processing apparatus 1 can collectively process N substrates W at the maximum. That is, the maximum number of substrates W in one lot is N. In this specification, “N” is an integer of 2 or more. For example, “N” may be an integer of 10 or more, an integer of 20 or more, an integer of 25 or more, an integer of 40 or more, or an integer of 50 or more. In preferred embodiment 1, an example of N=50 will be described. In addition, the minimum number of substrates W in one lot is 1.

In preferred embodiment 1, the substrate W is a semiconductor wafer. It is noted that examples of substrates W may include a substrate for a liquid crystal display device, a substrate for a plasma display, a substrate for a field emission display (FED), a substrate for an optical disk, a substrate for a magnetic disk, a substrate for a magneto-optical disk, a substrate for a photomask, a ceramic substrate, or a substrate for a solar cell. In preferred embodiment 1, a front surface of the substrate W indicates a principal surface of the substrate W.

The substrate processing apparatus 1 includes a processing tank 100, a substrate holder 110, a plurality of circulation processing liquid supplying nozzles 120, a circulation portion 130, at least one chemical liquid supplying portion 140, a diluent supplying portion 150, a draining portion 160, and a controller 170.

The processing tank 100 stores the processing liquid LQ. Then, the substrate W is immersed in the processing liquid LQ in the processing tank 100, and the substrate W is processed with the processing liquid LQ. In the example of FIG. 1, the processing liquid LQ is a liquid obtained by diluting a chemical liquid in a diluent. The chemical liquid supplying portion 140 supplies the chemical liquid to the processing tank 100. The diluent supplying portion 150 supplies the diluent to the processing tank 100.

The chemical liquid is, for example, an etching liquid. Examples of the chemical liquid include dilute hydrofluoric acid (DHF), hydrofluoric acid (HF), nitric hydrofluoric acid (mixed liquid of hydrofluoric acid and nitric acid (HNO₃)), buffered hydrofluoric acid (BHF), ammonium fluoride, HFEG (mixed liquid of hydrofluoric acid and ethylene glycol), phosphoric acid (H₃PO₄), sulfuric acid, acetic acid, nitric acid, hydrochloric acid, ammonia water, hydrogen peroxide water, an organic acid (for example, citric acid, oxalic acid), an organic alkali (for example, TMAH: tetramethylammonium hydroxide), sulfuric acid/hydrogen peroxide water mixture (SPM), ammonia/hydrogen peroxide water mixture (SC1), hydrochloric acid/hydrogen peroxide water mixture (SC2), isopropyl alcohol (IPA), a surfactant, a corrosion inhibitor, or a hydrophobizing agent.

The diluent is typically deionized water. Examples of the diluent may include carbonated water, electrolyzed ionized water, hydrogen water, ozone water, or an aqueous hydrochloric acid solution of dilute concentration (for example, approximately 10 ppm to 100 ppm). The diluent is also used as a rinse liquid. The rinse liquid is a liquid for washing away the processing liquid LQ, post-processing byproducts after processing with the processing liquid LQ, and/or foreign matter from the substrate W.

The substrate holder 110 holds the substrate W and immerses the substrate W in the processing liquid LQ stored in the processing tank 100. The plurality of circulation processing liquid supplying nozzles 120 supply the processing liquid LQ to the processing tank 100. The circulation portion 130 circulates the processing liquid LQ stored in the processing tank 100 and supplies the processing liquid LQ to each of the circulation processing liquid supplying nozzles 120. The draining portion 160 drains the processing liquid LQ in the processing tank 100. The following descriptions will be provided in

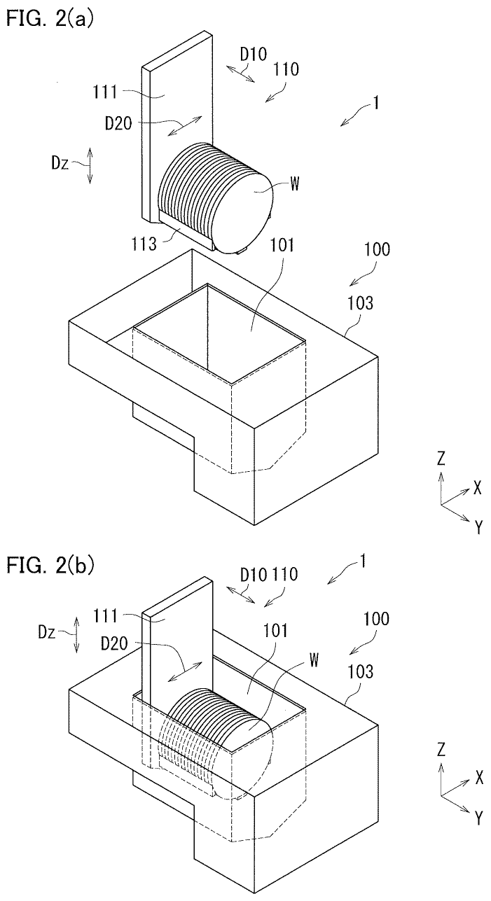

detail with reference to FIGS. 1, 2(a), and 2(b). As shown in FIG. 1, the processing tank 100 has a double tank structure including an inner tank 101 and an outer tank 103. The inner tank 101 and the outer tank 103 each have an upper opening that is open upward. The inner tank 101 is arranged to store the processing liquid LQ and be capable of housing the plurality of substrates W. The outer tank 103 is provided at an outer surface of the upper opening of the inner tank 101. The processing liquid LQ spilled over an upper edge of the inner tank 101 is recovered by the outer tank 103.

The substrate holder 110 holds at least one substrate W. The substrate holder 110 can hold N substrates W at the maximum. Specifically, the substrate holder 110 holds substrates W in one lot. The substrate holder 110 immerses the substrates W in one lot in the processing liquid LQ stored in the processing tank 100. The substrates W in one lot are substrates W to be collectively processed with the processing liquid LQ.

FIG. 2(a) is a perspective view showing a state of the substrate holder 110 before the substrate W is immersed in the processing liquid LQ. FIG. 2(b) is a perspective view showing the substrate holder 110 in a state where the substrate W is immersed in the processing liquid LQ. In FIGS. 2(a) and 2(b), the processing liquid LQ in the processing tank 100 is omitted in order to avoid overcomplicating the drawings.

As shown in FIGS. 1 and 2(a), the substrate holder 110 includes a main body plate 111, a plurality of holding rods 113, and an elevator 115. The main body plate 111 is a plate that extends in a vertical direction Dz. The holding rods 113 extend in a first direction D10 from one principal surface of the main body plate 111. The plurality of substrates W are held in a vertical orientation in a state of being aligned at intervals in the first direction D10 with a lower edge of each substrate W being brought in contact with the plurality of the holding rods 113.

The first direction D10 is substantially parallel to the horizontal direction and indicates a disposition direction of the plurality of substrates W. The substrate W is substantially perpendicular to the first direction D10. In addition, the substrate W is substantially parallel to a second direction D20. The second direction D20 is substantially orthogonal to the first direction D10 and is substantially parallel to the horizontal direction.

The first direction D10 corresponds to an example of a “predetermined direction” of the present invention.

The elevator 115 elevates and lowers the main body plate 111 between a retreat position shown in FIG. 2(a) and a processing position shown in FIG. 2(b). The retreat position indicates a position where the substrate W held by the holding rods 113 is disposed above the processing tank 100 (specifically, the inner tank 101). The processing position indicates a position where the substrate W held by the holding rods 113 is disposed in the processing tank 100 (specifically, the inner tank 101). The elevator 115 moves the main body plate 111 from the retreat position to the processing position, thereby causing the plurality of substrates W held by the holding rods 113 to be immersed in the processing liquid LQ.

Returning to FIG. 1, the plurality of circulation processing liquid supplying nozzles 120 supply the processing liquid LQ to the inner tank 101 of the processing tank 100. The plurality of circulation processing liquid supplying nozzles 120 are disposed at, inside the inner tank 101 of the processing tank 100, a bottom portion of the inner tank 101. Each of the circulation processing liquid supplying nozzles 120 is, for example, a pipe. Specifically, each of the circulation processing liquid supplying nozzles 120 has a plurality of processing liquid discharge ports 121. The circulation processing liquid supplying nozzle 120 supplies the processing liquid LQ to the inner tank 101 from the plurality of processing liquid discharge ports 121.

The circulation portion 130 includes a piping 131, a pump 132, a heater 133, a filter 134, an adjustment valve 135, and a valve 136. The pump 132, the heater 133, the filter 134, the adjustment valve 135, and the valve 136 are disposed at the piping 131 in this order from the upstream to the downstream.

The piping 131 guides the processing liquid LQ delivered from the processing tank 100 back to the processing tank 100. Specifically, an upstream end of the piping 131 is connected to an outer tank 114. Therefore, the piping 131 guides the processing liquid LQ from the outer tank 114 to the circulation processing liquid supplying nozzles 120. The plurality of circulation processing liquid supplying nozzles 120 are connected to a downstream end of the piping 131.

The pump 132 sends the processing liquid LQ from the piping 131 to the plurality of circulation processing liquid supplying nozzles 120. Therefore, the circulation processing liquid supplying nozzles 120 supply, to the inner tank 101, the processing liquid LQ supplied from the piping 131. The filter 134 filters the processing liquid LQ flowing in the piping 131.

The heater 133 heats to increase a temperature of the processing liquid LQ flowing in the piping 131. That is, the heater 133 adjusts the temperature of the processing liquid LQ.

The adjustment valve 135 adjusts a flow rate of the processing liquid LQ supplied to the plurality of circulation processing liquid supplying nozzles 120 by adjusting an opening degree of the piping 131. The valve 136 opens and closes the piping 131.

The chemical liquid supplying portion 140 includes a nozzle 142, a piping 144, and a valve 146. The nozzle 142 discharges the chemical liquid to the outer tank 103. The nozzle 142 is connected to the piping 144. The chemical liquid from a chemical liquid supply source TKA is supplied to the piping 144. The valve 146 is disposed in the piping 144. When the valve 146 is opened, the chemical liquid is discharged from the nozzle 142, and the chemical liquid is supplied into the outer tank 103.

The diluent supplying portion 150 includes a nozzle 152, a piping 154, and a valve 156. The nozzle 152 discharges the diluent to the outer tank 103. The nozzle 152 is connected to the piping 154. The diluent from the diluent supply source TKB is supplied to the piping 154. The valve 156 is disposed in the piping 154. When the valve 156 is opened, the diluent is discharged from the nozzle 152, and the diluent is supplied into the outer tank 103.

The draining portion 160 includes a drain piping 161 and a valve 163. The drain piping 161 is connected to a bottom wall of the inner tank 101 of the processing tank 100. The valve 163 is disposed in the drain piping 161. By opening the valve 163, the processing liquid LQ stored in the inner tank 101 is drained to the outside through the drain piping 161.

The controller 170 controls individual components of the substrate processing apparatus 1. Specifically, the controller 170 controls the substrate holder 110, the circulation portion 130, the chemical liquid supplying portion 140, the diluent supplying portion 150, and the draining portion 160. The controller 170 is, for example, a computer.

In addition, the controller 170 corrects a processing time of the substrates W based on a relationship between the number of substrates W in one lot and the etching rate.

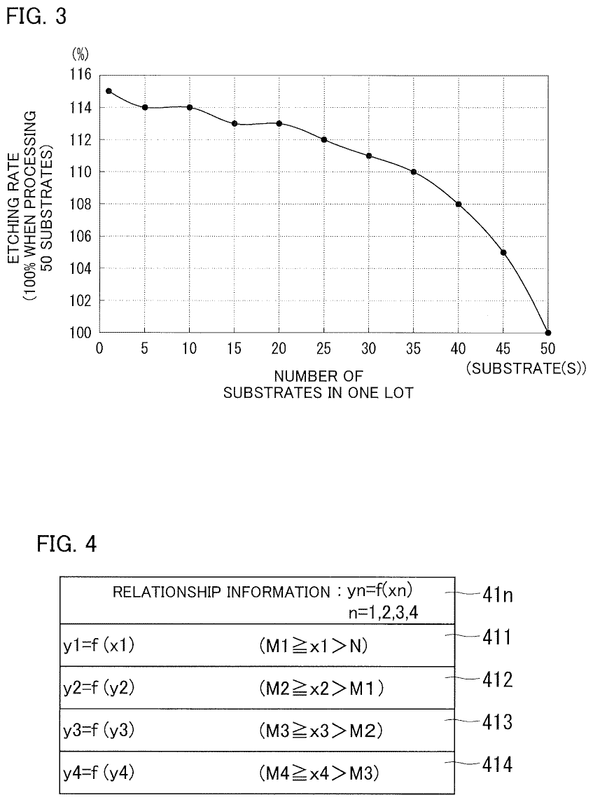

FIG. 3 is a graph showing a relationship between the number of substrates W in one lot and an etching rate. The etching rate is an etching amount of the substrate W per unit time. The abscissa of the graph represents the number of substrates W in one lot. The ordinate of the graph represents the etching rate of the substrate W. In FIG. 3, the etching rate is shown for each number of the substrates W constituting one lot, assuming that the etching rate when collectively processing 50 substrates W, which are the maximum number N of the substrates W in one lot, is 100%. The processing time with the processing liquid LQ in the processing tank 100 is the same regardless of the number of substrates W in one lot.

As shown in FIG. 3, the smaller the number of substrates W is in one lot, the higher the etching rate increases. Therefore, when the processing time is constant regardless of the number of substrates W, the smaller the number of substrates W in one lot is, the larger the etching amount increases. As a result, etching becomes excessive and exceeds a target etching amount. In particular, in a case where micro-etching needs to be performed on the substrate W, even when the amount exceeding the target etching amount is minute, the quality of the substrate W is significantly affected.

Thus, in preferred embodiment 1, the controller 170 sets the processing time shorter as the number of substrates W in one lot decreases, as compared with the processing time adopted in a case where the number of substrates W in one lot is the maximum number N.

As an example, the controller 170 determines a correction value in accordance with the number of the substrates W in one lot with respect to the processing time in the case where the number of substrates W in one lot is the maximum number N. The correction value is a real number of zero or more. The correction value is set to a larger value as the number of substrates W in one lot decreases. In the case where the number of substrates W in one lot is the maximum number N, the correction value of the processing time of the substrates W is zero. Therefore, the controller 170 subtracts a correction value in accordance with the number of substrates W from the processing time in the case where the number of substrates W in one lot is the maximum number N and sets a subtraction result as the corrected processing time. Since the correction value is set to a larger value as the number of substrates W in one lot decreases, the processing time after correction becomes shorter as the number of substrates W in one lot decreases.

However, as shown in FIG. 3, the number of substrates W in one lot and the etching rate are not in a proportional relationship. Therefore, it is not possible to perform accurate etching simply by linearly increasing the correction value at a constant gradient from the maximum number N to the minimum number (one) in one lot. Thus, in preferred embodiment 1, regarding the relationship between the number of substrates W in one lot and the correction value, a plurality of relationships are defined in accordance with a range of the number of substrates W in one lot.

Hereinafter, a linear increase of the correction value at a constant gradient from the maximum number N to the minimum number (one) in one lot is referred to at times as a “monotonic increase of the correction value.” In addition, in the present specification, the processing of the substrate W typically indicates etching processing.

FIG. 4 is a diagram showing an example of a plurality of items of relationship information 41n according to preferred embodiment 1. In the present specification, “n” included in a reference sign represents an integer of 1 or more. The plurality of items of relationship information 41n are different from each other. In the example of FIGS. 4, n=1, 2, 3, and 4. That is, FIG. 4 shows four items of relationship information 411, 412, 413, and 414.

The relationship information 411 indicates a relationship between the number x1 of substrates W and a correction value y1 of a processing time of the substrates W. The relationship information 411 is applied to a case where the number of substrates W in one lot that is a processing target is included in a number-of-substrates range (M1≥x1>N). The relationship information 411 is represented by a function “y1=f(x1).”

The relationship information 412 indicates a relationship between the number x2 of the substrates W and a correction value y2 of a processing time of the substrates W. The relationship information 412 is applied to a case where the number of substrates W in one lot that is a processing target is included in a number-of-substrates range (M2≥x2>M1). The relationship information 412 is represented by a function “y2=f(x2).”

The relationship information 413 indicates a relationship between the number x3 of substrates W and a correction value y3 of a processing time of the substrates W. The relationship information 413 is applied to a case where the number of substrates W in one lot that is a processing target is included in a number-of-substrates range (M3≥x3>M2). The relationship information 413 is represented by a function “y3=f(x3).”

The relationship information 414 indicates a relationship between the number x4 of substrates W and a correction value y4 of a processing time of the substrates W in a number-of-substrates range (M4≥x4>M3) of the substrates W in one lot. The relationship information 414 is applied to a case where the number of substrates W in one lot that is a processing target is included in a number-of-substrates range (M4≥x4>M3). The relationship information 414 is represented by a function “y4=f(x4).”

“N” denotes the maximum number of substrates W in one lot. “M1,” “M2,” “M3,” and “M4” are natural numbers less than N. In addition, M4<M3<M2<M1<N is established.

A function representing relationship information 41n can be generalized as yn=f(xn). Here, “xn” denotes the number of substrates W in one lot, and “yn” denotes a correction value. In preferred embodiment 1, as an example, the correction value yn is a positive value. When a processing time in a case where the number of substrates W in one lot is the maximum number N is denoted by “Tp” and the corrected processing time is denoted by “Tc,” the corrected processing time is represented by Expression (1).

$$Tc = Tp - yn \qquad ( 1 )$$

The controller 170 selects one item of relationship information 41n in accordance with the number xn of substrates W in one lot that is a processing target from the plurality of items of relationship information 41n, and corrects the processing time of the substrates W based on the selected relationship information 41n. Specifically, the controller 170 acquires a correction value yn in accordance with the number xn of substrates W from the selected relationship information 41n, and calculates a corrected processing time from Expression (1).

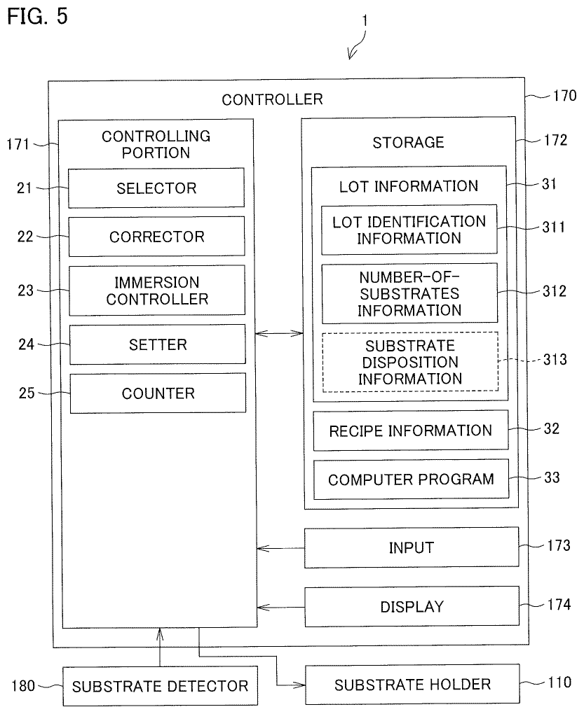

Next, details of the correction of the processing time will be described with reference to FIGS. 4 and 5. FIG. 5 is a block diagram showing the controller 170. As shown in FIG. 5, the controller 170 includes a controlling portion 171 (processor), a storage 172, an input 173, and a display 174. Also, the substrate processing apparatus 1 may further include a substrate detector 180.

The input 173 is input equipment for inputting various items of information into the controlling portion 171. Examples of the input 173 include a keyboard and a pointing device or a touch panel.

The display 174 displays various items of information. Examples of the display 174 include a liquid crystal display or an organic electroluminescence display.

The controlling portion 171 controls individual components of the substrate processing apparatus 1. The controlling portion 171 includes a selector 21, a corrector 22, an immersion controller 23, and a setter 24. The controlling portion 171 may further include a counter 25. The controlling portion 171 includes a processor such as a central processing unit (CPU).

The storage 172 stores various items of data. For example, the storage 172 stores lot information 31 and recipe information 32. The recipe information 32 is information for defining processing details and processing procedures of the substrates W. The recipe information 32 may be displayed on the display 174. The lot information 31 indicates information of a lot that is a processing target. The lot information 31 may be displayed on the display 174. The lot information 31 includes lot identification information 311 and number-of-substrates information 312. The lot identification information 311 is information for identifying a lot that is a processing target. The number-of-substrates information 312 indicates the number of substrates W included in the lot identified by the lot identification information 311. That is, the number-of-substrates information 312 indicates the number of substrates W in one lot. The lot information 31 may include substrate disposition information 313. The substrate disposition information 313 indicates disposition of the substrates W in the lot. The substrate disposition information 313 will be described in a first modification example below.

The storage 172 stores various computer programs. For example, the storage 172 stores a computer program 33 for executing the substrate processing method. The substrate processing method processes the substrates W by immersing at least one substrate W in the processing liquid LQ for each lot in a processing tank 100 that stores the processing liquid LQ.

The storage 172 includes a storage device. For example, the storage 172 includes a main storage device such as a semiconductor memory, and an auxiliary storage device such as a semiconductor memory or a hard disk drive. The main storage device typically includes a ROM and a RAM. The storage 172 may include a removable medium such as an optical disk. The storage 172 is an example of a non-transitory computer readable storage medium.

A processor of the controlling portion 171 executes, in a storage area (for example, on the RAM) of the storage 172, a computer program stored in the storage device of the storage 172 to control individual components of the substrate processing apparatus 1. For example, the controlling portion 171 executes a computer program 33 to function as the selector 21, the corrector 22, the immersion controller 23, and the setter 24. The controlling portion 171 may execute the computer program 33 to function as the selector 21, the corrector 22, the immersion controller 23, the setter 24, and the counter 25.

Then, the selector 21 acquires number-of-substrates information 312 from the storage 172. The selector 21 selects, from the plurality of items of relationship information 41n shown in FIG. 4, the relationship information 41n in accordance with the number xn of substrates W indicated by the number-of-substrates information 312. Therefore, according to preferred embodiment 1, the relationship information 41n more suitable for the processing of the number xn of substrates W indicated by the number-of-substrates information 312 can be selected, as compared with a case where the correction value is monotonically increased. That is, the relationship information 41n more suitable for the number xn of substrates W in the lot that is a processing target can be selected.

The corrector 22 acquires, from the selected relationship information 41n, the correction value yn in accordance with the number xn of substrates W indicated by the number-of-substrates information 312. Therefore, according to preferred embodiment 1, the correction value yn more suitable for the processing of the number xn of substrates W indicated by the number-of-substrates information 312 can be acquired, as compared with the case where the correction value is monotonically increased. That is, the correction value yn more suitable for the number xn of substrates W in the lot that is a processing target can be acquired.

The corrector 22 corrects the processing time of the substrates W based on the acquired correction value yn such that the processing time is shorter than the processing time in the case where the number of substrates W in the lot is the maximum number N. In this case, the corrector 22 corrects the processing time based on Expression (1). Specifically, the corrector 22 corrects the processing time of the substrates W based on the acquired correction value yn such that the processing time is shorter as the number xn of substrates W in the lot decreases, as compared with the processing time in the case where the number of the substrates W in the lot is the maximum number N. Therefore, according to preferred embodiment 1, the processing time more suitable for the processing of the number xn of substrates W indicated by the number-of-substrates information 312 can be set, as compared with the case where the correction value is monotonically increased. That is, the processing time more suitable for the number xn of substrates W in the lot that is a processing target can be set.

The immersion controller 23 controls the substrate holder 110 such that the substrates W are immersed in the processing liquid LQ in accordance with the corrected processing time of the substrates W. As a result, the substrates W are processed with the processing liquid LQ in the processing tank 100 based on the corrected processing time of the substrates W. This enables, according to preferred embodiment 1, the substrates W to be accurately processed in accordance with the number xn of substrates W in the lot that is a processing target, as compared with the case where the correction value is monotonically increased. For example, the substrates W can be accurately etched in accordance with the number xn of substrates W in the lot which is an etching target. In particular, even in a case where micro-etching needs to be performed on the substrate W, an etching amount can be prevented from exceeding a target etching amount. As a result, when the target etching amount is minute, the number of discarded substrates W due to an etching amount exceeding the target etching amount can be reduced. Also, since the etching can be prevented from exceeding the target etching amount, it is possible to reduce excessive mixing of etching residues into the processing liquid LQ. As a result, reduction in discarding frequency of the processing liquid LQ can be achieved.

Also, in preferred embodiment 1, each of the plurality of items of relationship information 41n is a function indicating a relationship between the number xn of substrates W in one lot and the correction value yn of the processing time of the substrates W. Therefore, there is no need to prepare a correction table for each number-of-substrates range of the substrates W in one lot. As a result, a configuration for acquiring the correction value yn can be easily built. The correction table is a table indicating a relationship between the number xn of substrates W in one lot and the correction value yn of the processing time of the substrates W. It is noted that, in preferred embodiment 1, the relationship information 41n is preferably a function, but may be a correction table.

Typically, the relationship information 41n is a linear function represented by Expression (2). Here, “an” denotes a gradient, and “bn” denotes an intercept. In preferred embodiment 1, the gradient an is a negative value.

$$yn = an \cdot xn + bn \qquad ( 2 )$$

Further, in preferred embodiment 1, four items of relationship information 41n are set. Therefore, the correction value in accordance with a change in etching rate with respect to the number of substrates W in one lot (FIG. 3) can be acquired by a relatively small number of items of relationship information 41n.

The substrate detector 180 and the counter 25 will be described with continuing reference to FIG. 5. The substrate detector 180 detects the substrates W in the lot that is a processing target one by one. Then, the substrate detector 180 outputs a substrate detection signal to the controlling portion 171 each time the substrate W is detected. For example, the substrate detector 180 is an optical sensor and optically detects the substrates W one by one while moving in the vertical direction Dz in a vessel (not shown) that accommodates unprocessed substrates W in one lot in a horizontal posture.

The counter 25 detects the number of substrates W in a lot that is a processing target by counting the substrate detection signals output each time the substrate detector 180 detects the substrates W. Then, the counter 25 stores, in the storage 172, the number-of-substrates information 312 indicating the number of substrates W in a lot that is a processing target. Also, the counter 25 may detect disposition of the substrates W in a lot that is a processing target based on the substrate detection signals. In this case, the counter 25 stores, in the storage 172, the substrate disposition information 313 indicating the disposition of the substrates W in a lot that is a processing target.

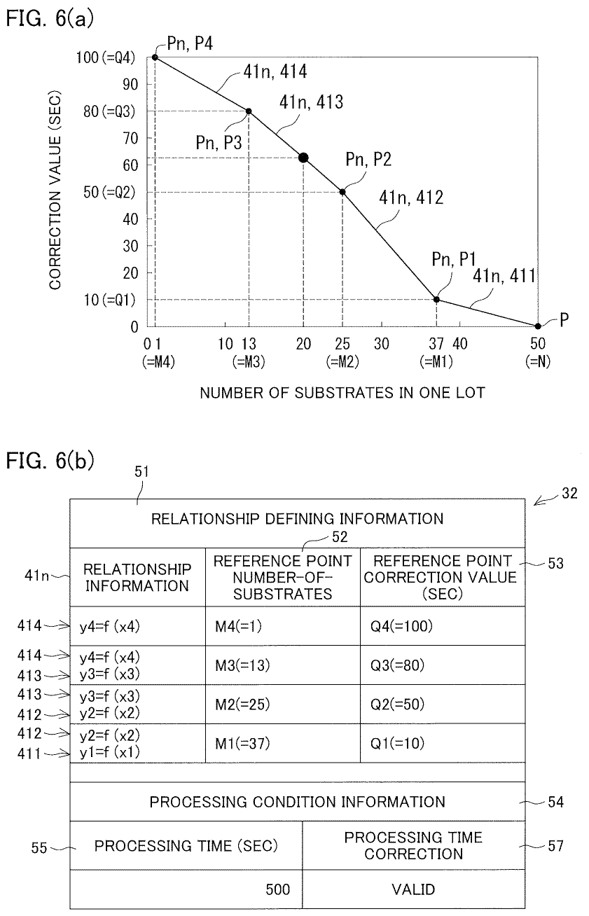

Next, examples of the correction value of the processing time will be described with reference to FIGS. 5, 6(a), and 6(b). FIG. 6(a) is a graph showing a plurality of items of relationship information 41n corresponding to a first example of the recipe information 32. The abscissa of the graph represents the number of substrates W in one lot. The ordinate of the graph represents a correction value (seconds) of the processing time of the substrates W. FIG. 6(b) is a diagram showing the first example of the recipe information 32.

As shown in FIG. 6(a), as an example, each of the plurality of items of relationship information 41n is represented by a linear function. The plurality of items of relationship information 41n are defined by a plurality of reference points Pn different from each other. In the example of FIG. 6(a), the plurality of items of relationship information 41n are defined by the plurality of reference points Pn different from each other and fixed points P. The reference points Pn can be changed.

Specifically, each of the plurality of items of relationship information 41n is defined by one or more reference points Pn. The reference point Pn indicates an end point of the relationship information 41n. The items of relationship information 412 to 414 other than the relationship information 411 are defined by two reference points Pn. The relationship information 411 is defined by one reference point Pn and a fixed point P. The fixed point P is a point at which the correction value indicates zero, and indicates an end point of the relationship information 411.

The relationship information 41n shown in FIG. 6(a) is defined in the recipe information 32 shown in FIG. 6(b).

As shown in FIG. 6(b), the recipe information 32 includes relationship defining information 51 and processing condition information 54. The relationship defining information 51 includes reference point number-of-substrates information 52 and reference point correction value information 53. The reference points Pn in FIG. 6(a) are determined by the reference point number-of-substrates information 52 and the reference point correction value information 53. The processing condition information 54 includes processing time information 55 and processing time correction information 57. The recipe information 32 may include relationship information 41n.

The plurality of items of reference point number-of-substrates information 52 respectively determine a plurality of reference points Pn. Each of the plurality of items of reference point number-of-substrates information 52 indicates the number of substrates W which determines the corresponding reference point Pn. In this case, the number of substrates W indicates the number of substrates W in one lot.

Specifically, each of items of the relationship information 412 to 414 other than the relationship information 411 is defined by two items of reference point number-of-substrates information 52. For example, as shown in FIGS. 6(a) and 6(b), the relationship information 412 is defined by the number M1 of substrates and the number M2 of substrates indicated by the reference point number-of-substrates information 52. The relationship information 411 is defined by one item of reference point number-of-substrates information 52 and fixed point number-of-substrates information. The fixed point number-of-substrates information indicates the maximum number N which is the number of substrates W at the fixed point P. For example, the relationship information 411 is defined by the number M1 of substrates indicated by the reference point number-of-substrates information 52 and the maximum number N of substrates indicated by the fixed point number-of-substrates information.

The plurality of items of reference point correction value information 53 respectively determine a plurality of reference points Pn. Each of the plurality of items of reference point correction value information 53 indicates a correction value of the processing time of the substrate W which determines the corresponding reference point Pn. In other words, the reference point correction value information 53 indicates the correction value of the processing time for the number of substrates W indicated by the reference point number-of-substrates information 52.

More specifically, each of the items of relationship information 412 to 414 other than the relationship information 411 is defined by two items of reference point correction value information 53. For example, as shown in FIGS. 6(a) and 6(b), the relationship information 412 is defined by a correction value Q1 and a correction value Q2 indicated by the reference point correction value information 53. The relationship information 411 is defined by one item of reference point correction value information 53 and fixed point correction value information. The fixed point correction value information indicates “zero” which is a correction value of the processing time at the fixed point P. For example, the relationship information 411 is defined by the correction value Q1 indicated by the reference point correction value information 53 and a correction value (0) indicated by the fixed point correction value information.

A user uses the input 173 to input the numbers M1 to M4 of substrates W in the reference point number-of-substrates information 52 and the correction values Q1 to Q4 in the reference point number-of-substrates information 52. The setter 24 receives inputs of the numbers M1 to M4 of substrates W and the correction values Q1 to Q4. The setter 24 sets the numbers M1 to M4 of substrates W and the correction values Q1 to Q4 as the recipe information 32. It is noted that the user uses the input 173 to input the maximum number N of substrates of the fixed point number-of-substrates information and the correction value (0) of the fixed point correction value information.

The relationship information 41n is calculated by the setter 24 based on the reference point number-of-substrates information 52, the reference point correction value information 53, the fixed point number-of-substrates information (the maximum number N of substrates), and the fixed point correction value information (0). Then, the relationship information 41n is stored in the storage 172.

For example, in a case where the relationship information 412 is represented by a linear function (y2=a2·x2+b2), the setter 24 calculates a gradient a2 and an intercept b2 based on the numbers M1 and M2 of substrates in the reference point number-of-substrates information 52 and the correction values Q1 and 02 in the reference point correction value information 53. As a result, the relationship information 414 is derived.

For example, in a case where the relationship information 411 is represented by a linear function (y1=a1·x1+b1), the setter 24 calculates a gradient a1 and an intercept b1 based on the number M1 of substrates in the reference point number-of-substrates information 52, the maximum number N of substrates in the fixed point number-of-substrates information, the correction value Q1 in the reference point correction value information 53, and the correction value (0) in the fixed point correction value information. As a result, the relationship information 411 is derived.

The processing time information 55 indicates an uncorrected processing time of the substrate W. In other words, the processing time information 55 indicates the processing time in a case where the number of substrates W in one lot is the maximum number N. This is because the correction value is zero in the case where the number of substrates W in one lot is the maximum number N.

The processing time correction information 57 indicates whether or not the correction processing based on the relationship information 41n is performed with respect to the processing time indicated by the processing time information 55. For example, “VALID” denotes that the correction processing is performed, and “INVALID” denotes that the correction processing is not performed.

A specific example of correction of the processing time will be described with continuing reference to FIGS. 6(a) and 6(b). As shown in FIG. 6(a), in a case where the number of substrates W in one lot that is a processing target which is indicated by the number-of-substrates information 312 is 20, the selector 21 selects the relationship information 413 from the plurality of items of relationship information 411 to 414.

Then, the corrector 22 acquires, from the relationship information 413, a correction value (62 seconds) when the number of substrates W in one lot is 20. Specifically, the corrector 22 inputs “20” in the number “x3” of substrates W in Expression (2) indicating the relationship information 413 and acquires “62 sec” as the correction value “y3.”

Further, the corrector 22 subtracts the correction value (62 seconds) from the processing time (500 seconds) indicated by the processing time information 55 of the recipe information 32 shown in FIG. 6(b), and sets the subtraction result (438 seconds) as the corrected processing time. Specifically, the corrector 22 inputs “500 seconds” in the processing time “Tp” of Expression (1), inputs “62 seconds” in the correction value “y3,” and acquires “438 seconds” as the corrected processing time “Tc.”

As described above with reference to FIGS. 5, 6(a), and 6(b), according to preferred embodiment 1, the setter 24 receives the inputs of the plurality of items of reference point number-of-substrates information 52 which respectively determine the plurality of reference points Pn. Therefore, the user can change the relationship information 41n by changing the reference point number-of-substrates information 52 based on an actual result of processing of the substrates W by the substrate processing apparatus 1 (for example, an actual result of an etching rate). As a result, it is possible to set the relationship information 41n which is more suitable for the user.

Also, according to preferred embodiment 1, the setter 24 receives inputs of the plurality of items of reference point correction value information 53 which respectively determine the plurality of reference points Pn. Therefore, the user can change the relationship information 41n by changing the reference point correction value information 53 based on the actual result of the processing of the substrate W by the substrate processing apparatus 1 (for example, the actual result of the actual etching rate). As a result, it is possible to set the relationship information 41n which is more suitable for the user.

Further, according to preferred embodiment 1, the reference point correction value information 53 defines a number-of-substrates range of the substrates W to which the relationship information 41n is applied. For example, as shown in FIG. 4, the number-of-substrates range of the substrates W to which the relationship information 412 is applied is a range of more than the number M1 and equal to or less than the number M2. The user can change the reference point correction value information 53, thereby being able to change the number-of-substrates range of the substrates W to which the relationship information 41n is applied. As a result, it is possible to set the relationship information 41n which is more suitable for the user.

Further, according to preferred embodiment 1, the correction value of the processing time of the substrates W in the case where the number of substrates W in one lot is the maximum number N is zero. Then, in each of the plurality of items of relationship information 41n, the correction value of the processing time of the substrates W increases, as the number of the substrates W decreases. The corrector 22 corrects the processing time of the substrates W by subtracting the correction value in accordance with the number of substrates W indicated by the number-of-substrates information 312 from the processing time of the substrates W in the case where the number of substrates W in one lot is the maximum number N. Therefore, according to preferred embodiment 1, in the case where the number of substrates W in one lot is often the maximum number N, the number of lots which are correction targets can be reduced when a plurality of lots are processed. As a result, a processing load on the controller 170 can be reduced.

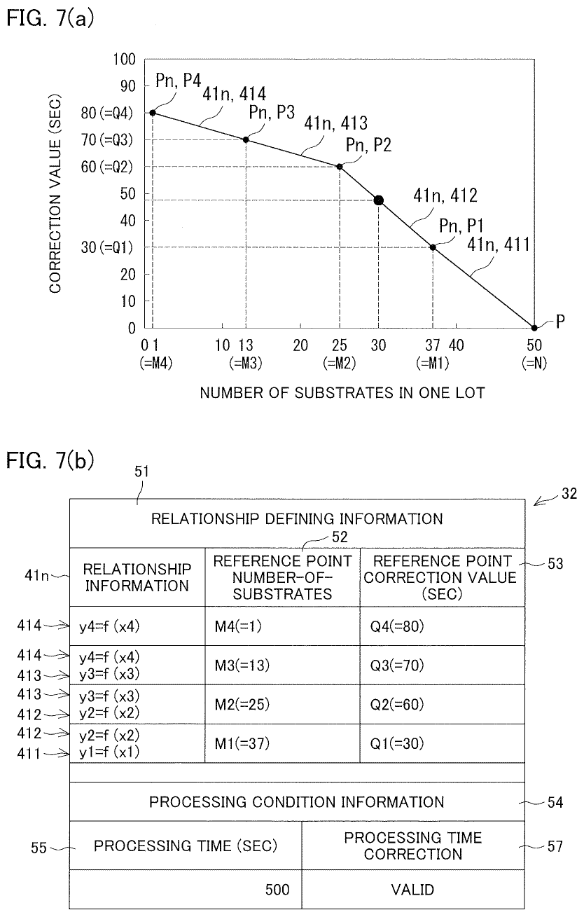

Next, a setting example of the reference point correction value information 53 will be described with reference to FIGS. 5 to 7(b). FIG. 7(a) is a graph showing a plurality of items of relationship information 41n corresponding to a second example of the recipe information 32. FIG. 7(b) is a diagram showing the second example of the recipe information 32. In the second example, a correction value of the reference point correction value information 53 of the recipe information 32 is changed from the correction value of the reference point correction value information 53 of the first example shown in FIG. 6(b).

As can be understood by comparing FIGS. 6(a) and 6(b) and FIGS. 7(a) and 7(b), the user can change the relationship information 41n by changing the reference point correction value information 53 in the recipe information 32.

For example, the items of relationship information 411 to 414 in FIG. 6(a) can be changed to items of relationship information 411 to 414 in FIG. 7(b) by changing the correction values Q4 (=100), Q3 (=80), Q2 (=50), and Q1 (=10) of the reference point correction value information 53 in FIG. 6(b) to the correction values Q4 (=80), Q3 (=70), Q2 (=60), and Q1 (=30) of the reference point correction value information 53 in FIG. 7(b), respectively.

Specifically, the user inputs the correction value of the reference point correction value information 53 by the input 173. The setter 24 receives an input of the correction value of the reference point correction value information 53. The setter 24 sets the correction value of the reference point correction value information 53 as the recipe information 32. As a result, the items of relationship information 41n is changed.

A specific example of correction of the processing time will be described with continuing reference to FIGS. 7(a) and 7(b). As shown in FIG. 7(a), in a case where the number of substrates W in one lot that is a processing target which is indicated by the number-of-substrates information 312 is 30, the selector 21 selects the relationship information 412 from the plurality of items of relationship information 411 to 414.

Then, the corrector 22 acquires, from the relationship information 412, a correction value (48 seconds) when the number of substrates W in one lot is 30 (refer to Expression (2)).

Further, the corrector 22 subtracts the correction value (48 seconds) from the processing time (500 seconds) indicated by the processing time information 55 of the recipe information 32 shown in FIG. 7(b), and sets the subtraction result (452 seconds) as the corrected processing time (refer to Expression (1)).

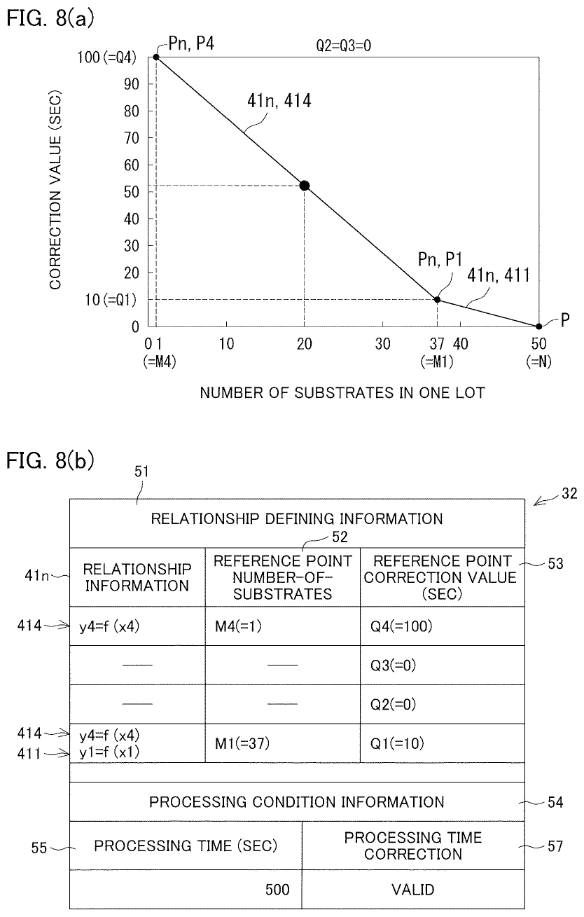

Next, a setting example of the number of items of relationship information 41n will be described with reference to FIGS. 5, 6(a), 6(b), 8(a), and 8(b). FIG. 8(a) is a graph showing a plurality of items of relationship information 41n corresponding to a third example of the recipe information 32. FIG. 8(b) is a diagram showing the third example of the recipe information 32. In the third example, the number of items of relationship information 41n is changed. In FIG. 6(a), the number of items of relationship information 41n is “4,” and in FIG. 8(a), the number of items of relationship information 41n is “2.”

The user can decrease the number of items of relationship information 41n as shown in FIG. 8(a) by setting a first specific value for the reference point correction value information 53 shown in FIG. 8(b). In the third example of FIG. 8(b), the first specific value is zero. Also, in the third example, the correction values Q3 and Q2 of the reference point correction value information 53 are set as the first specific values. Therefore, the number of items of relationship information 41n decreases from “4” in the first example of FIGS. 6(a) to “2” in the third example of FIG. 8(a). In the third example, inputs of the first specific values can be received with respect to the correction values Q1 to Q3 of the reference point correction value information 53.

For example, the four items of relationship information 411 to 414 in FIG. 6(a) can be decreased to two items of relationship information 411 and 414 in FIG. 8(b) by changing the correction values Q2 (=50) and Q3 (=80) of the reference point correction value information 53 in FIG. 6(b) to the correction values Q2 (=0) and Q3 (=0) of the reference point correction value information 53 in FIG. 8(b), respectively.

In this case, the relationship information 414 is defined by the numbers M1 and M4 of substrates indicated by the reference point number-of-substrates information 52 and the correction values Q1 and 04 indicated by the reference point correction value information 53.

Specifically, the user inputs, through the input 173, the first specific value as the reference point correction value information 53 in which the setting of the first specific values is permitted, from the plurality of items of reference point correction value information 53. The setter 24 receives the input of the first specific values. The setter 24 sets the first specific values as the items of reference point correction value information 53 of the recipe information 32. As a result, the items of relationship information 41n corresponding to the first specific values indicated by the items of reference point correction value information 53 are deleted or invalidated. That is, the number of items of relationship information 41n can be changed.

A specific example of correction of the processing time will be described with continuing reference to FIGS. 8(a) and 8(b). As shown in FIG. 8(a), in a case where the number of substrates W in one lot that is a processing target which is indicated by the number-of-substrates information 312 is 20, the selector 21 selects the relationship information 414 from the plurality of items of relationship information 411 to 414.

Then, the corrector 22 acquires, from the relationship information 414, a correction value (52 seconds) when the number of substrates W in one lot is 20 (refer to Expression (2)).

Further, the corrector 22 subtracts the correction value (52 seconds) from the processing time (500 seconds) indicated by the processing time information 55 of the recipe information 32 shown in FIG. 8(b), and sets the subtraction result (448 seconds) as the corrected processing time (refer to Expression (1)).

As described above with reference to FIGS. 5, 8(a), and 8(b), according to preferred embodiment 1, the setter 24 receives the input of the first specific value for setting the number of the plurality of items of relationship information 41n. Therefore, the number of items of relationship information 41n can be changed. As a result, it is possible to set the items of relationship information 41n of a more suitable number for the user.

The first specific value corresponds to an example of “number setting information” of the present invention.

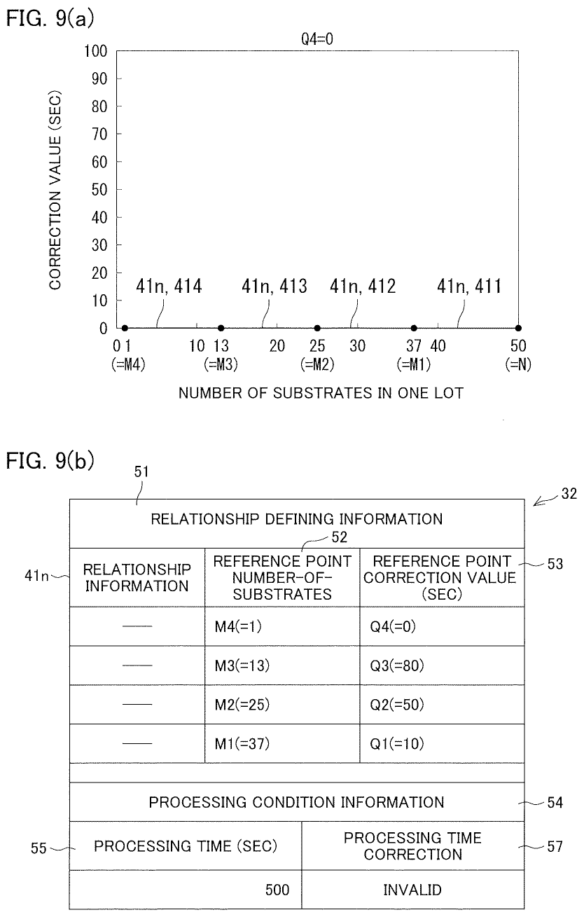

Next, invalid setting of the relationship information 41n will be described with reference to FIGS. 5, 9(a), and 9(b). FIG. 9(a) is a graph showing a plurality of items of relationship information 41n corresponding to a fourth example of the recipe information 32. FIG. 9(b) is a diagram showing the fourth example of the recipe information 32. In the fourth example, all of the items of relationship information 41n are invalidated. That is, the correction of the processing time is not executed.

The user can invalidate all of the items of relationship information 41n as shown in FIG. 9(a) by setting a second specific value as the correction value Q4 of the reference point correction value information 53 shown in FIG. 9(b). That is, a correction value of a processing time is set to zero without depending on the number of substrates W in one lot, and correction is not executed. In the fourth example of FIG. 9(b), the second specific value is zero. In the fourth example, an input of the second specific value can be received with respect to the correction value Q4 of the reference point correction value information 53.

For example, as shown in FIG. 9(b), by setting the correction value Q4 of the reference point correction value information 53 to zero, all of the items of relationship information 411 to 414 can be invalidated.

Specifically, the user inputs, by the input 173, the second specific value as the correction value Q4 of the reference point correction value information 53. The setter 24 receives the input of the second specific value. The setter 24 sets the second specific value as the correction value Q4 of the reference point correction value information 53 of the recipe information 32. As a result, all of the items of relationship information 41n are set to be invalid. In this case, the setter 24 sets “INVALID” indicating that the correction processing is not performed on the processing time correction information 57.

On the other hand, as long as the second specific value is not set as the correction value Q4 of the reference point correction value information 53, the setter 24 sets “VALID” indicating that the correction processing is performed on the processing time correction information 57.

As described above with reference to FIGS. 5, 9(a), and 9(b), according to preferred embodiment 1, the setter 24 receives the input of the second specific value representing invalidation of a function of correcting the processing time of the substrate W. Therefore, the function of correcting the processing time of the substrate W can be invalidated. This enables user convenience to be improved.

The second specific value corresponds to an example of “invalid setting information” of the present invention.

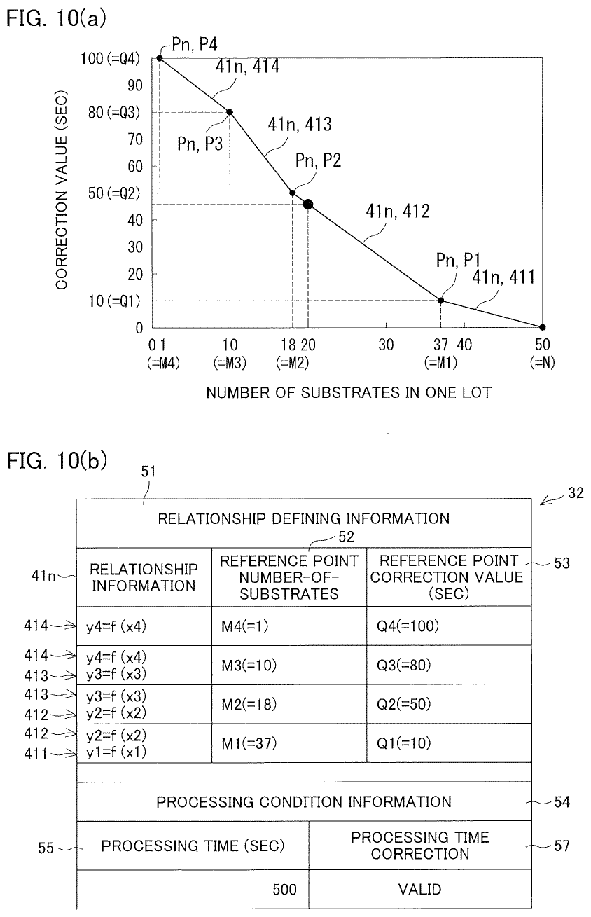

Next, a setting example of the reference point number-of-substrates information 52 will be described with reference to FIGS. 5, 6(a), 6(b), 10(a), and 10(b). FIG. 10(a) is a graph showing a plurality of items of relationship information 41n corresponding to a fifth example of the recipe information 32. FIG. 10(b) is a diagram showing the fifth example of the recipe information 32. In the fifth example, the number of substrates W in the reference point number-of-substrates information 52 of the recipe information 32 is changed from the number of substrates W in the reference point number-of-substrates information 52 of the first example shown in FIGS. 6(a) and 6(b).

As can be understood by comparing FIGS. 6(a) and 6(b) and FIGS. 10(a) and 10(b), the user can change the relationship information 41n by changing the reference point number-of-substrates information 52 in the recipe information 32.

For example, the items of relationship information 412 to 414 in FIG. 6(a) can be changed to the items of relationship information 412 to 414 in FIG. 10(b) by changing the numbers M2 (=25) and M3 (=13) of substrates W in the reference point number-of-substrates information 52 in FIG. 6(b) to the numbers M2 (=10) and M3 (=18) of substrates W in the reference point number-of-substrates information 52 in FIG. 10(b), respectively.

Specifically, the user inputs the number of substrates W in reference point number-of-substrates information 52 by the input 173. The setter 24 receives inputs of the number of substrates W in the reference point number-of-substrates information 52. The setter 24 sets the number of substrates W in the reference point number-of-substrates information 52 as the recipe information 32. As a result, the items of relationship information 41n is changed.

A specific example of correction of the processing time will be described with continuing reference to FIGS. 10(a) and 10(b). As shown in FIG. 10(a), in a case where the number of substrates W in one lot that is a processing target which is indicated by the number-of-substrates information 312 is 20, the selector 21 selects the relationship information 412 from the plurality of items of relationship information 411 to 414.

Then, the corrector 22 acquires, from the relationship information 412, a correction value (48 seconds) when the number of substrates W in one lot is 20 (refer to Expression (2)).

Further, the corrector 22 subtracts the correction value (48 seconds) from the processing time (500 seconds) indicated by the processing time information 55 of the recipe information 32 shown in FIG. 10(b), and sets the subtraction result (452 seconds) as the corrected processing time (refer to Expression (1)).

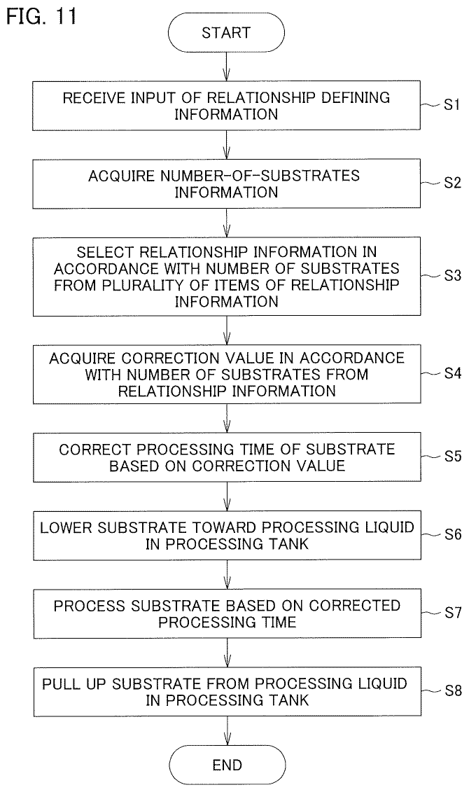

Next, the substrate processing method according to preferred embodiment 1 will be described with reference to FIGS. 5 and 11. FIG. 11 is a flowchart showing a substrate processing method according to preferred embodiment 1. The substrate processing method processes the substrates W by immersing at least one substrate W in the processing liquid LQ for each lot in a processing tank 100 that stores the processing liquid LQ. That is, the substrate processing method processes the substrates W for each lot by immersing the substrates W in the processing liquid LQ stored in the processing tank 100 by the substrate holder 110 that holds at least one substrate W. The substrate processing method is executed by the substrate processing apparatus 1. As shown in FIG. 11, the substrate processing method includes steps S1 to S8. Specifically, the controller 170 executes steps S1 to S8 by executing the computer program 33 on the storage 172. That is, the computer program 33 causes the controller 170 to execute steps S1 to S8.

As shown in FIGS. 5 and 11, first, in step S1, the setter 24 receives the input of the relationship defining information 51 through the input 173. The setter 24 sets the received relationship defining information 51 as the recipe information 32.

For example, in step S1, the setter 24 receives the inputs of the plurality of items of reference point correction value information 53 respectively which determine the plurality of reference points Pn (FIGS. 6(a), 6(b), 7(a), and 7(b)). For example, in step S1, the setter 24 receives the inputs of the first specific values for setting the number of the plurality of items of relationship information 41n (FIGS. 8(a) and 8(b)). For example, in step S1, the setter 24 receives the input of the second specific value which invalidates the function of correcting the processing time of the substrate W (FIGS. 9(a) and 9(b)). For example, in step S1, the setter 24 receives the inputs of the plurality of items of reference point number-of-substrates information 52 which respectively determine the plurality of reference points Pn (FIGS. 6(a), 6(b), FIGS. 10(a), and 10(b)).

Next, in step S2, the selector 21 acquires, from the storage 172, the number-of-substrates information 312 indicating the number of substrates W included in the lot that is a processing target.

Next, in step S3, the selector 21 selects the relationship information 41n in accordance with the number of substrates W indicated by the number-of-substrates information 312, from the plurality of items of relationship information 41n, each of which indicates the relationship between the number of substrates W and the correction value of the processing time of the substrates W.

Nest, in step S4, the corrector 22 acquires, from the selected relationship information 41n, the correction value in accordance with the number of substrates W indicated by the number-of-substrates information 312. For example, the corrector 22 acquires the correction value from Expression (2).

Next, in step S5, the corrector 22 corrects the processing time of the substrates W based on the acquired correction value such that the processing time is shorter than the processing time in the case where the number of substrates W in the lot that is a processing target is the maximum number N. For example, the corrector 22 corrects the processing time by Expression (1).

Next, in step S6, the immersion controller 23 controls the substrate holder 110 such that the substrates W in the lot that is a processing target are lowered toward the processing liquid LQ in the processing tank 100. As a result, the substrate holder 110 lowers the substrates W toward the processing liquid LQ in the processing tank 100.

Next, in step S7, the immersion controller 23 controls the substrate holder 110 such that the substrates W are immersed in the processing liquid LQ in accordance with the corrected processing time of the substrates W. Therefore, the substrates W are processed with the processing liquid LQ in the processing tank 100 based on the corrected processing time of the substrates W. For example, the immersion controller 23 controls the substrate holder 110 such that the state in which the substrates W are immersed is maintained in accordance with the corrected processing time.

Next, in step S8, the immersion controller 23 controls the substrate holder 110 such that the substrates W in the lot that is a processing target are pulled up from the processing liquid LQ in the processing tank 100. As a result, the substrate holder 110 pulls up the substrates W from the processing liquid LQ in the processing tank 100. Then, the substrate processing method ends.

As described above with reference to FIG. 11, according to the substrate processing method of preferred embodiment 1, the relationship information 41n in accordance with the number of substrates W is selected from the plurality of items of relationship information 41n (step S3). Therefore, the relationship information 41n more suitable for the number of substrates W in the lot that is a processing target can be selected, as compared with the case where the correction value is monotonically increased. Then, a correction value in accordance with the number of substrates W is acquired from the selected relationship information 41n (step S4). Therefore, the correction value more suitable for the number of substrates W in the lot that is a processing target can be acquired, as compared with the case where the correction value is monotonically increased. Then, the processing time is corrected based on the acquired correction value (step S5), and the substrates W are processed in accordance with the corrected processing time (step S7). Therefore, the substrates W can be accurately processed in accordance with the number of substrates W in the lot that is a processing target, as compared with the case where the correction value is monotonically increased. In particular, even in a case where micro-etching needs to be performed on the substrate W, an etching amount can be prevented from exceeding a target etching amount. As a result, when the target etching amount is minute, the number of discarded substrates W due to an etching amount exceeding the target etching amount can be reduced.

### First Modification Example

A first modification example of the preferred embodiment 1 will be described with reference to FIGS. 5 and 11 to 14(b). The first modification example is mainly different from preferred embodiment 1 described above with reference to FIGS. 1 to 11 in that the processing time of the substrate W is corrected in accordance with a disposition state of the substrates W in the lot. Differences between the first modification example and preferred embodiment 1 described above will mainly be described below.

In the first modification example, in step S4 in FIG. 11, the corrector 22 sets the correction value in accordance with the disposition of the substrates W in the processing tank 100. Therefore, the correction value of the processing time of the substrate W depends on the disposition of the substrates W in the processing tank 100. As a result, even when the number of substrates W in one lot is the same, the correction value may be different when the disposition of the substrates W is different. Then, in step S5, the corrector 22 corrects the processing time of the substrates W based on the correction value set in step S4. As a result, according to the first modification example, the processing time can be corrected by the correction value reflecting characteristics of an etching rate in accordance with the disposition of the substrates W. This enables the substrates W to be further accurately processed in accordance with the number and the disposition of substrates W in the lot that is a processing target.

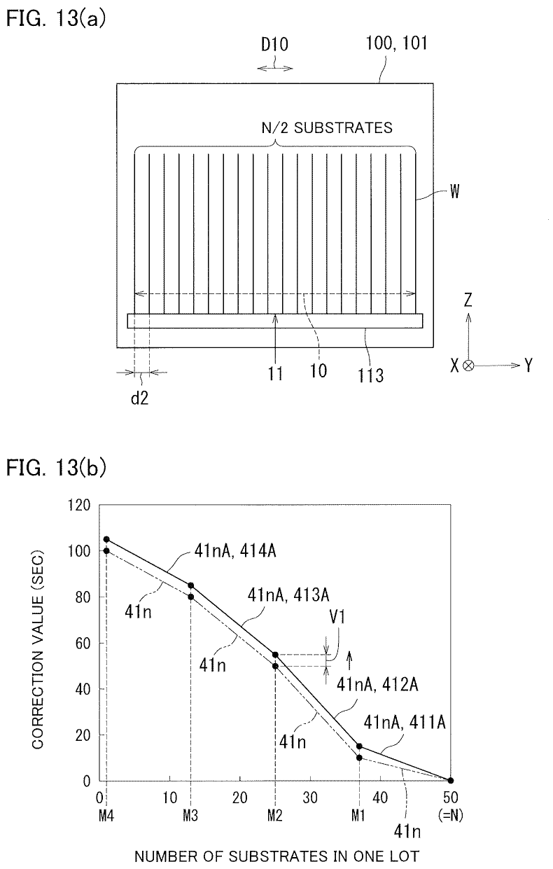

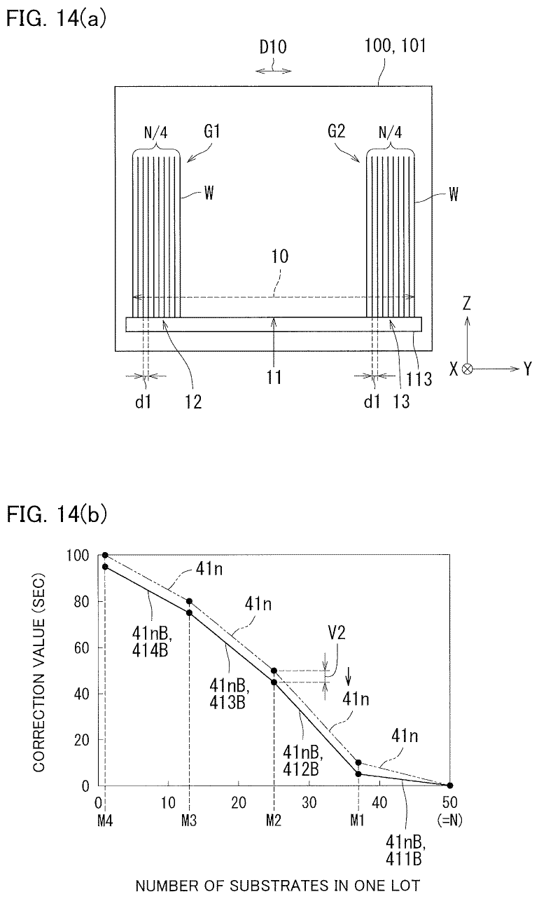

As an example, in a case where the substrates W in one lot are disposed in a first disposition state, a second disposition state, or a third disposition state, the corrector 22 corrects the processing time based on relationship information 41nA (FIG. 13(b)) or relationship information 41nB (FIG. 14(b)) different from the relationship information 41n in a reference disposition state. The reference disposition state is different from the first disposition state, the second disposition state, and the third disposition state.

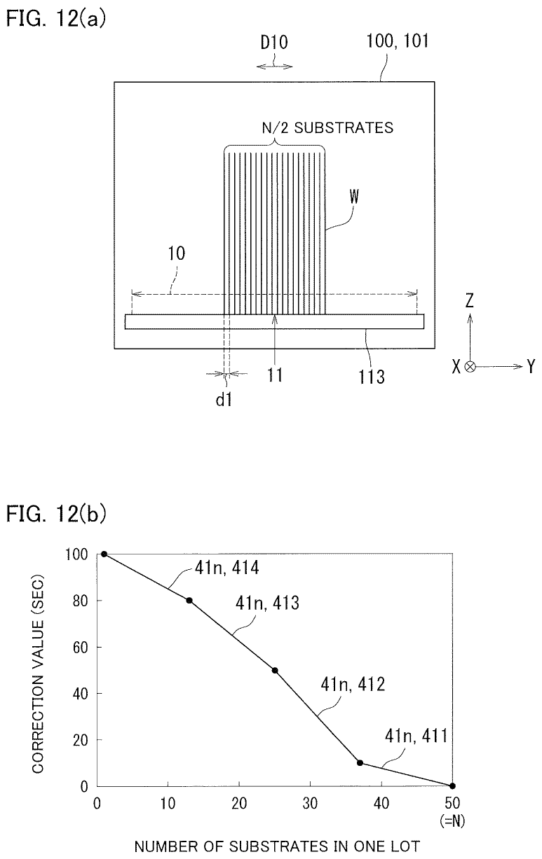

FIG. 12(a) is a view showing the reference disposition information of the substrates W according to the first modification example. In FIG. 12(a), as an example, N/2 substrates W are held by the holding rods 113. FIG. 12(b) is a graph showing a plurality of items of relationship information 41n corresponding to the reference disposition state of the substrates W according to the first modification example. The abscissa of the graph represents the number of substrates W in one lot. The ordinate of the graph represents a correction value of the processing time of the substrates W.

As shown in FIG. 12(a), the reference disposition state of the substrates W is a state in which the substrates W are continuously disposed at equal intervals in the first direction D10 in the processing tank 100, and the substrates W are disposed in a region including a central portion 11 of a substrate disposition maximum region 10 in the first direction D10, and in the state, an interval between the adjacent substrates W indicates a first distance d1. The substrate disposition maximum region 10 indicates a region where the substrates W are disposed in the processing tank 100 in a case where the number of substrates W in the lot is the maximum number N.

In a case where a state of the substrates W in the lot that is a processing target shows the reference disposition state, the corrector 22 corrects the processing time based on the relationship information 41n selected from the plurality of items of relationship information 41n shown in FIG. 12(b). This point is the same as in preferred embodiment 1.

FIG. 13(a) is a view showing first disposition information of the substrates W. In FIG. 13(a), as an example, N/2 substrates W are held by the holding rods 113. FIG. 13(b) is a graph showing the plurality of items of relationship information 41nA corresponding to the first disposition state of the substrates W.

As shown in FIG. 13(a), the first disposition state of the substrates W is a state in which the substrates W are disposed at equal intervals in the first direction D10 in the processing tank 100, and an interval between the adjacent substrates W is a second distance d2 longer than the first distance d1 (FIG. 12(a)). The first distance d1 is equal to a distance between the substrate W and the substrate W in the case where the number of substrates W in the lot is the maximum number N.

In step S4 in FIG. 11, in a case where the substrates W are disposed in the first disposition state in the processing tank 100, the corrector 22 sets a correction value of the processing time of the substrates W disposed in the first disposition state such that a corrected processing time of the substrates W is shorter than a corrected processing time of the substrates W disposed in the reference disposition state (FIG. 12(a)).

The reason for this setting is as follows. That is, since the substrates W in the first disposition state are disposed at wider intervals (sparse disposition density) than the substrates W in the reference disposition state, a fresh processing liquid LQ is easily brought into contact with front surfaces of the substrates W. Therefore, even when the number of substrates W in one lot is the same in the first disposition state and the reference disposition state, the substrates W in the first disposition state are more easily processed than the substrates W in the reference disposition state. As a result, when the substrates W in the first disposition state are processed in the same processing time as the substrates W in the reference disposition state, there is a possibility that a processing amount exceeds a target processing amount. Thus, in the first disposition state, the correction is executed such that the corrected processing time is shorter than that in the reference disposition state. That is, even when the number of the substrates W in the lot is the same, the correction value in the first disposition state is larger than the correction value in the reference disposition state. As a result, the substrates W can be further accurately processed in accordance with the number of substrates W in the first disposition state.

For example, as shown in FIG. 13(b), in the first disposition state, the reference point correction value information 53 used in the reference disposition state is increased by a first value V1. As a result, the relationship information 41nA used in the first disposition state is shifted such that the correction value is increased with respect to the relationship information 41n used in the reference disposition state. In this case, in step S3 in FIG. 11, the selector 21 selects, from the plurality of items of relationship information 41nA, the relationship information 41nA in accordance with the number of substrates W indicated by the number-of-substrates information 312. Then, in step S4, the corrector 22 acquires, from the selected relationship information 41nA, the correction value in accordance with the number of substrates W. Further, in step S5, the processing time of the substrates W is corrected based on the acquired correction value.

Alternatively, for example, the selector 21 selects, from the plurality of items f relationship information 41n, the relationship information 41n in accordance with the number of substrates W indicated by the number-of-substrates information 312. Then, the corrector 22 acquires, from the selected relationship information 41n, a correction value in accordance with the number of substrates W. Further, the corrector 22 may add the first value V1 to the acquired correction value and set the addition result as a new correction value. Then, the corrector 22 corrects the processing time based on the newly set correction value.

As described above, the relationship information 41nA of the first disposition state may be created such that the correction value is larger than that from the relationship information 41n used in the reference disposition state, or the addition result obtained by adding a value to the correction value acquired from the relationship information used in the reference disposition state may be set as the correction value used in the first disposition state.

FIG. 14(a) is a view showing second disposition information of the substrates W. FIG. 14(b) is a graph showing the plurality of items of relationship information 41nB corresponding to the second disposition state of the substrates W.

As shown in FIG. 14(a), the second disposition state of the substrates W is a state in which the plurality of substrates W are disposed in the processing tank 100 upon being divided into a first substrate group G1 and a second substrate group G2 and. In FIG. 14(a), as an example, each of the first substrate group G1 and the second substrate group G2 includes N/4 substrates W. The first substrate group G1 and the second substrate group G2 are not disposed in the central portion 11 of the substrate disposition maximum region 10. The first substrate group G1 and the second substrate group G2 are separated in the first direction D10.

The first substrate group G1 is disposed in an end region 12 on one side of the substrate disposition maximum region 10 in the first direction D10. The second substrate group G2 is disposed in an end region 13 on another side of the substrate disposition maximum region 10 in the first direction D10. In each of the first substrate group G1 and the second substrate group G2, there is a state in which two or more substrates W are disposed at equal intervals in the first direction D10 and an interval between the adjacent substrates W indicates the first distance d1.

In step S4 in FIG. 11, in a case where the substrates W are disposed in the second disposition state in the processing tank 100, the corrector 22 sets a correction value of the processing time of the substrates W disposed in the second disposition state such that a corrected processing time of the substrates W is longer than a corrected processing time of the substrates W disposed in the reference disposition state (FIG. 12(a)).

The reason for this setting is as follows. That is, the substrates W in the second disposition state are disposed at the same intervals as the substrates W in the reference disposition state in each of the first substrate group G1 and the second substrate group G2, but the first substrate group G1 is disposed in the end region 12 on the one side, and the second substrate group G2 is disposed in the end region 13 on the other side. Therefore, there is a possibility that the first substrate group G1 and the second substrate group G2 will be affected by the convection of the processing liquid LQ in the processing tank 100. As a result, when the substrates W in the second disposition state are processed in the same processing time as the substrates W in the reference disposition state, there is a possibility that the processing amount does not reach the target processing amount. Thus, in the second disposition state, the correction is executed such that the corrected processing time is longer than that in the reference disposition state. That is, even when the number of the substrates W in the lot is the same, the correction value in the second disposition state is smaller than the correction value in the reference disposition state. As a result, the substrates W can be further accurately processed in accordance with the number of substrates W in the second disposition state.

For example, as shown in FIG. 14(b), in the second disposition state, the reference point correction value information 53 used in the reference disposition state is decreased by a second value V2. As a result, the relationship information 41nB used in the second disposition state is shifted such that the correction value is decreased with respect to the relationship information 41n used in the reference disposition state. In this case, in step S3 in FIG. 11, the selector 21 selects, from the plurality of items of relationship information 41nB, the relationship information 41nB in accordance with the number of substrates W indicated by the number-of-substrates information 312. Then, in step S4, the corrector 22 acquires, from the selected relationship information 41nB, the correction value in accordance with the number of substrates W. Further, in step S5, the processing time of the substrates W is corrected based on the acquired correction value.

Alternatively, for example, the selector 21 selects, from the plurality of items of relationship information 41n, the relationship information 41n in accordance with the number of substrates W indicated by the number-of-substrates information 312. Then, the corrector 22 acquires, from the selected relationship information 41n, a correction value in accordance with the number of substrates W. Further, the corrector 22 may subtract the second value V2 from the acquired correction value and set the subtraction result as a new correction value. Then, the corrector 22 corrects the processing time based on the newly set correction value.

As described above, the relationship information 41nB of the second disposition state may be created such that the correction value is smaller than that from the relationship information used in the reference disposition state, or the subtraction result obtained by subtracting a value from the correction value acquired from the relationship information 41n used in the reference disposition state may be set as the correction value used in the second disposition state.

Also, in step S4 in FIG. 11, in a case where the substrates W are disposed in the third disposition state in the processing tank 100, the corrector 22 sets a correction value of the processing time of the substrates W disposed in the third disposition state such that a corrected processing time of the substrates W is longer than a corrected processing time of the substrates W disposed in the reference disposition state (FIG. 12(a)). The reason is the same as that in the case of the second disposition state.

The third disposition state of the substrates W is a state in which the plurality of substrates W in the lot are disposed, in the processing tank 100, in either the first substrate group G1 or the second substrate group G2. Also, the correction value used in the third disposition state is similar to the correction value used in the second disposition state.

### Second Modification Example

A second modification example of preferred embodiment 1 will be described with reference to FIGS. 5, 15, and 16. The second modification example is mainly different from preferred embodiment 1 described above with reference to FIGS. 1 to 11 in that the processing time of the substrates W is divided into a plurality of step periods. Differences between the second modification example and preferred embodiment 1 described above will mainly be described below.

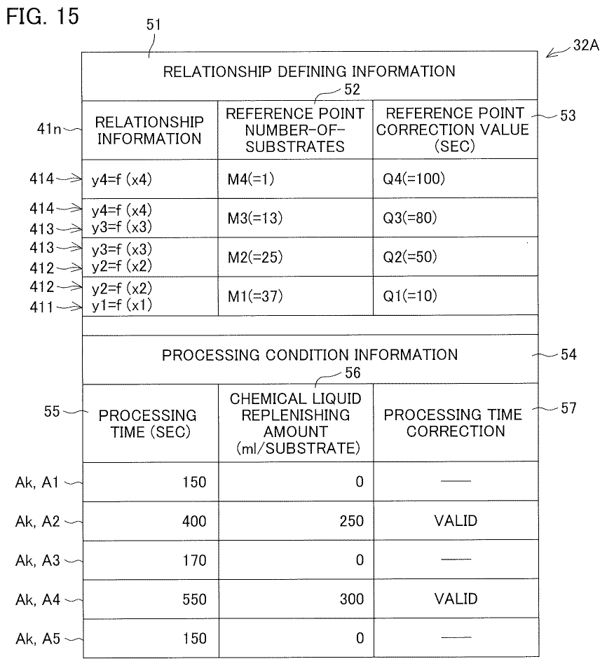

FIG. 15 is a diagram showing recipe information 32A according to the second modification example. As shown in FIG. 15, in the recipe information 32A, the processing condition information 54 further includes chemical liquid replenishing amount information 56. The chemical liquid replenishing amount information 56 indicates a replenishing amount of a chemical liquid with respect to the processing tank 100. In the example of FIG. 15, the chemical liquid replenishing amount information 56 indicates the replenishing amount of the chemical liquid per one substrate W. The processing tank 100 is replenished with the chemical liquid by the chemical liquid supplying portion 140. The storage 172 stores the recipe information 32A.

Also, the processing time before correction indicated by the processing time information 55 is divided into a plurality of step periods Ak. Therefore, the step periods Ak of the recipe information 32A indicate periods before correction. In this description, “k” included in a reference sign represents an integer of 1 or more

In the example of FIGS. 15, k=1, 2, 3, 4, and 5. In this case, the processing time indicated by the processing time information 55 is divided into step periods A1 to A5. In at least one step period Ak of the step periods A1 to A5, the chemical liquid supplying portion 140 replenishes the processing tank 100 with the chemical liquid. In the example of FIG. 15, the processing tank 100 is replenished with the chemical liquid in the step periods A2 and A3. The reason that the replenishment of the chemical liquid is performed by being divided into multiple times instead of being performed at a time is, for example, to prevent a deviation in concentration of the chemical liquid from occurring in the processing tank 100.

The corrector 22 corrects the step periods A2 and A4 set as periods in which the chemical liquid is replenished, of the plurality of step periods Ak, based on the correction value acquired from the relationship information 41n selected by the selector 21. Therefore, according to the second modification example, the step periods A2 and A4 more suitable for the number xn of substrates W in the lot that is a processing target can be set, as compared with the case where the correction value is monotonically increased. In particular, by correcting the step periods A2 and A4 in which the chemical liquid is replenished, it is possible to effectively prevent the processing amount of the substrate W from exceeding the target processing amount. Hereinafter, the corrected step period Ak is referred to at times as a step period Tk.

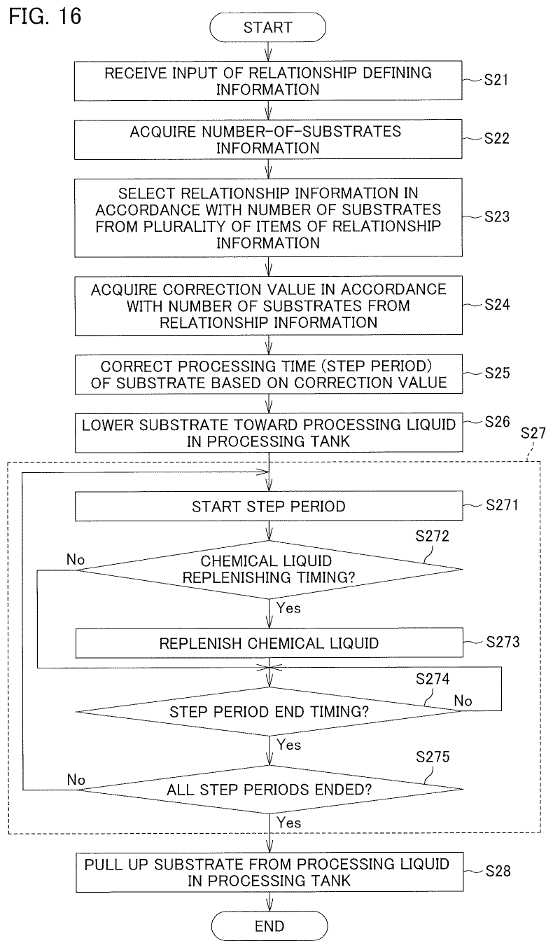

Next, a substrate processing method according to the second modification example will be described with reference to FIGS. 5 and 16. FIG. 16 is a flowchart showing the substrate processing method according to a second modification example. As shown in FIG. 16, the substrate processing method includes steps S21 to S28. Specifically, the controller 170 executes steps S21 to S28 by executing the computer program 33. That is, the computer program 33 causes the controller 170 to execute steps S21 to S28.

Steps S21 to S28 are executed as shown in FIG. 16. Steps S21 to S28 are the same as steps S1 to S8 in FIG. 1, respectively.

In particular, in step S25, the corrector 22 corrects, of the plurality of step periods Ak, a step period Ak set as a period in which the chemical liquid is replenished, based on the correction value acquired in step S24.

In this case, in step S25, the corrector 22 corrects the two or more step periods Ak by equally or proportionally distributing the correction value acquired in step S24 to the two or more step periods Ak in which the chemical liquid is replenished. Therefore, according to the second modification example, the correction value acquired from the relationship information 41n can be distributed to two or more step periods Ak by simple processing.

Specifically, in the case of equal distribution of the correction value acquired in step S24 to two or more step periods Ak, the corrector 22 calculates, by Expression (3), a correction value Yn after the equal distribution. In Expression (3), “yn” denotes the correction value acquired from the relationship information 41n (refer to Expression (2)), and “J” denotes the number of two or more step periods Ak in which the chemical liquid is replenished.

$$Yn = yn / J \qquad ( 3 )$$

In this case, the corrector 22 calculates the corrected step periods Tk by Expression (4). In Expression (4), “Ak” denotes step periods before correction which are indicated by the processing time information 55, and “Yn” denotes a correction value after equal distribution which is represented by Expression (3).

$$Tk = Ak - Yn \qquad ( 4 )$$

A specific example of the correction of the step periods Ak will be described with reference to FIGS. 6(a) and 15. As shown in FIG. 6(a), in a case where the number of substrates W in one lot that is a processing target which is indicated by the number-of-substrates information 312 is 20, the selector 21 selects the relationship information 413 from the plurality of items of relationship information 411 to 414.

Then, the corrector 22 acquires, from the relationship information 413, a correction value y3 (=62 seconds) when the number of substrates W in one lot is 20. Further, the corrector 22 equally distributes the acquired correction value y3 (=62 seconds) by Expression (3) and acquires a correction value Y3 (=31 seconds) after the equal distribution. In the example of FIG. 15, in Expression (3), J=2.

Further, the corrector 22 substitutes, into Expression (4), the correction value Y3 (=31 seconds) and the step period A2 (=400 seconds) in which the chemical liquid is replenished, and obtains a corrected step period T2 (=369 seconds). Also, the corrector 22 substitutes, into Expression (4), the correction value Y3 (=31 seconds) and the step period A4 (=550 seconds) in which the chemical liquid is replenished, and obtains a corrected step period T4 (=519 seconds).

On the other hand, in a case where the correction value acquired in step S24 is proportionally distributed to two or more step periods Ak, the corrector 22 proportionally distributes the correction value acquired in step S24 to the step periods Ak, in accordance with lengths of the two or more step periods Ak in which the chemical liquid is replenished. In the case of executing the proportional distribution, the corrector 22 calculates the corrected step period Tk by substituting, into the expression (4), a correction value after the proportional distribution with respect to “Yn.”

Hereinafter, regarding “Yn” in Expression (4), in a case where the equal distribution and the proportional distribution are not distinguished, “Yn” is referred to at times as a “distribution correction value.”

Returning to FIG. 16, in step S27, the substrates W are processed with the processing liquid LQ in the processing tank 100 based on the uncorrected step periods Ak and the corrected step periods Tk. In the example of FIG. 15, the uncorrected step periods Ak are the step periods A1, A3, and A5, and the corrected step periods Tk are the step periods T2 and T4. In step S27, according to the recipe information 32A, the step periods proceed in the order of step periods A1, T2, A3, T4, and A5.

Specifically, step S27 includes steps S271 to S275.

First, in step S271, the immersion controller 23 starts the step periods Ak or the step periods Tk, according to the order of the step periods in the recipe information 32A. For example, the immersion controller 23 starts a timer that measures the step periods Ak or the step periods Tk.

Next, in step S272, the immersion controller 23 determines whether or not a replenishing timing of the chemical liquid has arrived. That is, the immersion controller 23 determines whether or not the step period Tk in which the chemical liquid is replenished has started.

In a case where it is determined in step S272 that the replenishing timing of the chemical liquid has not arrived (No), that is, in a case where the uncorrected step period Ak is started, the processing proceeds to step S274.

On the other hand, in a case where it is determined in step S272 that the replenishing timing of the chemical liquid has arrived (Yes), that is, in a case where the corrected step period Tk is started, the processing proceeds to step S273.

Next, in step S273, the immersion controller 23 controls the chemical liquid supplying portion 140 to replenish the processing tank 100 with the chemical liquid. That is, the immersion controller 23 controls the chemical liquid supplying portion 140 to replenish the processing tank 100 with the chemical liquid in the corrected step period Tk. As a result, in the corrected step period Tk, the chemical liquid supplying portion 140 replenishes the processing tank 100 with the chemical liquid.

In this case, the immersion controller 23 calculates a total replenishing amount of the chemical liquid in the step periods Tk by multiplying a chemical liquid replenishing amount (ml/substrate) indicated by the chemical liquid replenishing amount information 56 of the recipe information 32A by the number of substrates W indicated by the number-of-substrates information 312. In this case, the chemical liquid replenishing amount (ml/substrate) in the step period Ak before correction which corresponds to the step period Tk is used as a chemical liquid replenishing amount (ml/substrate) in the corrected step period Tk.

For example, in the corrected step period T2 of the step period A2 in FIG. 15, in a case where a chemical liquid replenishing amount in the chemical liquid replenishing amount information 56 is 250 (ml/substrate) and the number of substrates W in the number-of-substrates information 312 is 20, the total replenishing amount of the chemical liquid is 5000 (ml). For example, in the corrected step period T4 of the step period A4 in FIG. 15, in a case where a chemical liquid replenishing amount in the chemical liquid replenishing amount information 56 is 300 (ml/substrate) and the number of substrates W in the number-of-substrates information 312 is 20, the total replenishing amount of the chemical liquid is 6000 (ml).

The immersion controller 23 controls the chemical liquid supplying portion 140 to replenish the processing tank 100, in each of the step periods Tk, with the chemical liquid of the calculated total replenishing amount.

Next, in step S274, the immersion controller 23 determines whether or not an end timing of the ongoing step period has arrived. The ongoing step period is the step period Ak or the step period Tk, according to the order of the step periods in the recipe information 32A.

In a case where it is determined in step S274 that the end timing of the step period has not arrived (No), step S274 is repeated until the end timing arrives.

On the other hand, in a case where it is determined in step S274 that the end timing of the step period has arrived (Yes), the processing proceeds to step S275.

Next, in step S275, the immersion controller 23 determines whether or not all of the step periods (for example, the step periods A1, T2, A3, T4, A5) constituting the processing time of the substrate W have ended.

In a case where it is determined in step S275 that all of the step periods have not ended (No), the processing proceeds to step S271.

On the other hand, in a case where it is determined in step S275 that all of the step periods have ended (Yes), the processing proceeds to step S28. Then, after completion of step S28, the substrate processing method ends.

### Preferred Embodiment 2

A substrate processing system SYS according to preferred embodiment 2 of the present invention will be described with reference to FIGS. 5 and 17 to 19. Preferred embodiment 2 is mainly different from the second modification example of preferred embodiment 1 described above with reference to FIGS. 15 and 16 in that the correction value reflecting the characteristics of each of a plurality of substrate processing apparatuses 1 is derived. Differences between preferred embodiment 2 and the second modification example will mainly be described below.

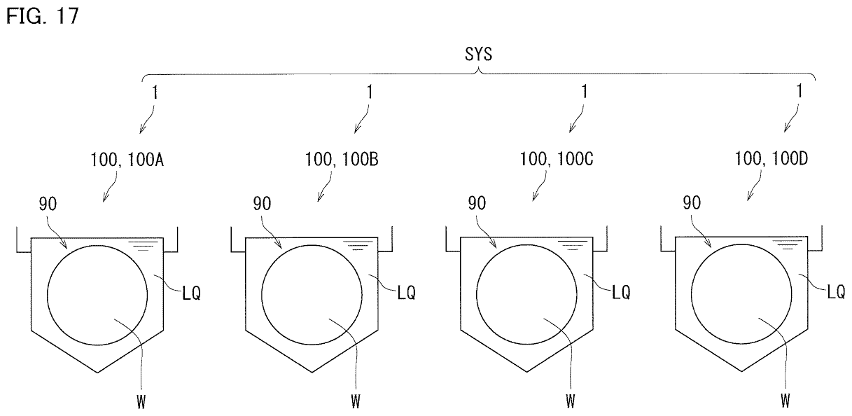

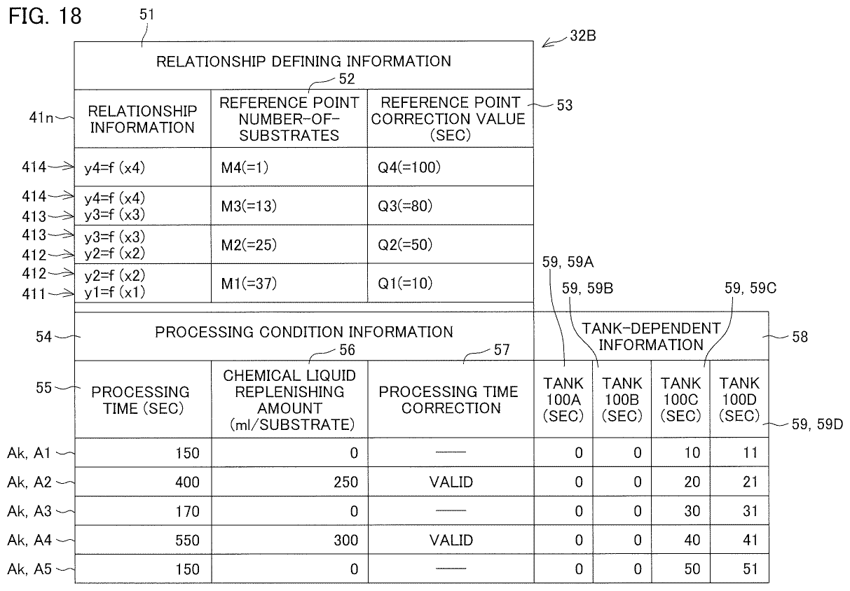

FIG. 17 is a view showing the substrate processing system SYS according to preferred embodiment 2. FIG. 18 is a diagram showing recipe information 32B according to preferred embodiment 2. The recipe information 32B is stored in the storage 172.

As shown in FIG. 17, the substrate processing system SYS includes a plurality of substrate processing apparatuses 1. Each of the plurality of substrate processing apparatuses 1 includes the processing tank 100. In the example of FIG. 17, the substrate processing system SYS includes four substrate processing apparatuses 1. Therefore, the substrate processing system SYS includes four processing tanks 100A to 100D. As an example, the substrate processing system SYS includes one controller 170 (FIG. 5). It is noted that the substrate processing system SYS may include a plurality of controllers 170 respectively corresponding to the plurality of substrate processing apparatuses 1.

In preferred embodiment 2, a plurality of lots 90 are processed in a plurality of processing tanks 100A to 100D, respectively. Each of the plurality of lots 90 includes one or more and N or less substrates W.

As shown in FIG. 18, the recipe information 32B includes tank-dependent information 58. The tank-dependent information 58 includes a plurality of items of tank-dependent correction value information 59. The plurality of items of tank-dependent correction value information 59 are respectively assigned to the plurality of processing tanks 100. The tank-dependent correction value information 59 indicates a tank-dependent correction value. The tank-dependent correction values indicate correction values for correcting processing times of the substrates W in accordance with processing characteristics of the corresponding processing tanks 100. The processing characteristics are properties related to capacity (processing capacity) of the processing tank 100 to process the substrates W. For example, the lower the etching rate, the lower the processing capacity.

Even in a case where the same number of substrates W are processed under the same processing condition in the plurality of processing tanks 100, the processing amount (for example, the etching rate) of the substrates W may be different between the processing tanks 100 due to effects of environments inside and/or outside the processing tanks 100 and a tolerance of components of the processing tanks 100. Therefore, the processing characteristics may be different between the processing tanks 100.

The corrector 22 corrects the processing time of the substrates W based on the correction value acquired from the relationship information 41n and the tank-dependent correction value. Therefore, in a case where the plurality of processing tanks 100 are provided, the processing time can be corrected by reflecting the processing characteristics of the processing tank 100. As a result, according to preferred embodiment 2, it is possible to prevent variations in the processing amount (for example, the etching amount) of the substrates W between the plurality of processing tanks 100.

Hereinafter, the tank-dependent correction value will be described with reference to specific examples. Also, the tank-dependent correction value information 59 assigned to the processing tank 100A is referred to at times as tank-dependent correction value information 59A, the tank-dependent correction value information 59 assigned to the processing tank 100B is referred to at times as tank-dependent correction value information 59B, the tank-dependent correction value information 59 assigned to the processing tank 100C is referred to at times as tank-dependent correction value information 59C, and the tank-dependent correction value information 59 assigned to the processing tank 100D is referred to at times as tank-dependent correction value information 59D.

In preferred embodiment 2, of the plurality of processing tanks 100, one or more processing tanks 100 are set as reference processing tanks. The reference processing tank is the processing tank 100 having the tank-dependent correction value set to zero which is indicated by the tank-dependent correction value information 59. In the example of FIG. 18, the processing tanks 100A and 100B are set as the reference processing tanks. Also, in the individual items of tank-dependent correction value information 59, a tank-dependent correction value is set for each of the plurality of step periods Ak. Regarding the processing tanks 100A and 100B, which are reference processing tanks, the tank-dependent correction value is set to zero for all of the step periods Ak.

The corrector 22 calculates a corrected step period Uk by Expression (5) or (6). Expression (5) is selected by the corrector 22 in a case where the correction based on the relationship information 41n is executed for the step periods Ak. On the other hand, Expression (6) is selected by the corrector 22 in a case where the correction based on the relationship information 41n is not executed for the step periods Ak.

In Expression (5), “Tk” denotes a corrected step period represented by the above Expression (4), “Rk” denotes a tank-dependent correction value, and “Yn” denotes a distribution correction value of Expression (4).

$$Uk = Tk + Rk = Ak - Yn + Rk \qquad ( 5 )$$

$$Uk = Ak + Rk \qquad ( 6 )$$

As an example, the lower the processing capacity as a characteristic of the processing tank 100, the larger the value of the tank-dependent correction value Rk is set. As a result, the lower the processing capacity of the processing tank 100, the longer the corrected step period Uk is set.

The tank-dependent correction value Rk of the processing tank 100 having a characteristic of processing capacity lower than that of the reference processing tank is larger than the tank-dependent correction value Rk of the reference processing tank. Therefore, the tank-dependent correction value Rk of the processing tank 100 having a characteristic of low processing capacity takes a positive value. This is because the tank-dependent correction value Rk of the reference processing tank is zero.

On the other hand, the tank-dependent correction value Rk of the processing tank 100 having a characteristic of processing capacity higher than that of the reference processing tank is smaller than the tank-dependent correction value Rk of the reference processing tank. Therefore, the tank-dependent correction value Rk of the processing tank 100 having the characteristic of high processing capacity takes a negative value. This is because the tank-dependent correction value Rk of the reference processing tank is zero.

In preferred embodiment 2, of the processing tanks 100A to 100D, the processing tanks 100A and 100B having a characteristic of the highest processing capacity are set as the reference processing tanks. Therefore, as shown in FIG. 18, the tank-dependent correction values Rk of the processing tanks 100C and 100D indicated by the items of tank-dependent correction value information 59C and 59D take positive values. The tank-dependent correction values Rk of the processing tanks 100C and 100D other than the reference processing tanks are determined in advance based on, for example, a difference between an actual value of the processing amount (for example, the etching rate) of the substrates W in the processing tank 100A which is the reference processing tank and actual values of the processing amounts (for example, the etching rate) of the substrates W in the processing tanks 100C and 100D.

As shown in FIG. 18, in the recipe information 32B, for example, the tank-dependent correction value information 59C for the processing tank 100C includes a tank-dependent correction value R1 (=10 seconds) in the step period A1, a tank-dependent correction value R2 (=20 seconds) in the step period A2, a tank-dependent correction value R3 (=30 seconds) in the step period A3, a tank-dependent correction value R4 (=40 seconds) in the step period A4, and a tank-dependent correction value R5 (=50 seconds) in the step period A5.

A correction example in a case where 20 substrates W are processed in the processing tank 100C will be described with continuing reference to FIG. 18. In this case, the items of relationship information 41n in FIGS. 6(a) and 6(b) are used. The step period A1 is corrected based on Expression (6), and a corrected step period U1 is 160 seconds (=150+10). The step period A2 is corrected based on the Expression (5), and a corrected step period U2 is 389 seconds (=369+20). In this case, “369 seconds” indicates the step period T2, and is cited from the “specific example of the correction of the step periods Ak” of the second modification example described with reference to FIGS. 6(a) and 15. The step period A3 is corrected based on Expression (6), and a corrected step period U3 is 200 seconds (=170+30). The step period A4 is corrected based on the Expression (5), and a corrected step period U4 is 559 seconds (=519+40). In this case, “519 seconds” indicates the step period T4, and is cited from the “specific example of the correction of the step periods Ak” of the second modification example described with reference to FIGS. 6(a) and 15. The step period A5 is corrected based on Expression (6), and a corrected step period U5 is 200 seconds (=150+50).

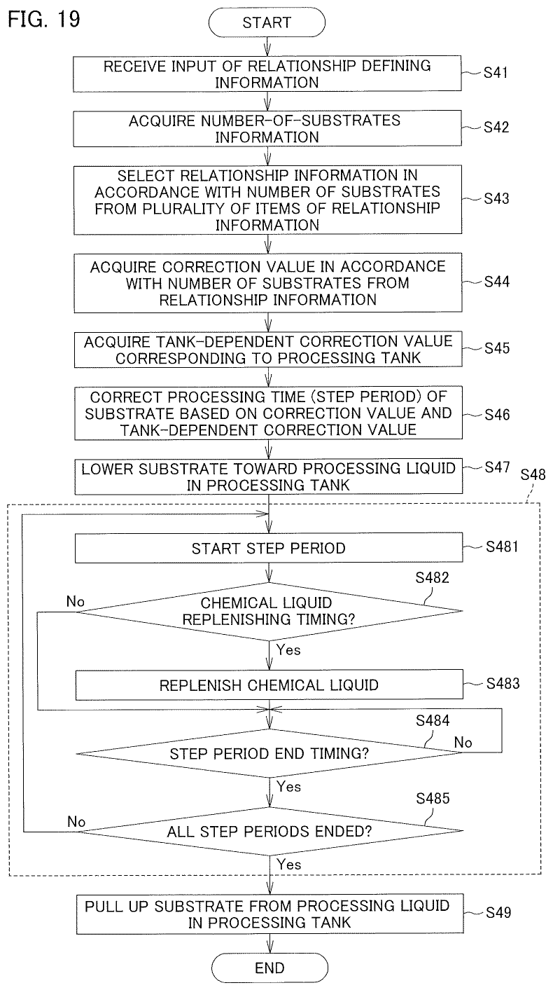

Next, the substrate processing method according to preferred embodiment 2 will be described with reference to FIGS. 5 and 19. FIG. 19 is a flowchart showing a substrate processing method according to preferred embodiment 2. As shown in FIG. 19, the substrate processing method includes steps S41 to S49. Specifically, the controller 170 executes steps S41 to S49 by executing the computer program 33 on the storage 172. That is, the computer program 33 causes the controller 170 to execute steps S41 to S49.

As shown in FIG. 19, steps S41 to S44 are executed. Steps S41 to S44 are the same as steps S21 to S24 in FIG. 16, respectively.

In preferred embodiment 2, in step S45, the corrector 22 acquires, from the recipe information 32B (FIG. 18) stored in the storage 172, the tank-dependent correction value of the tank-dependent correction value information 59 assigned to the processing tank 100 that is a control target, of the plurality of processing tanks 100.

Next, in step S46, the corrector 22 corrects the processing time of the substrate W based on the correction value acquired in step S44 and the tank-dependent correction value acquired in step S45.

Specifically, in step S46, the corrector 22 corrects each step period Ak based on the correction value acquired in step S44 and the tank-dependent correction value acquired in step S45 and obtain each corrected step period Uk. In this case, the corrector 22 uses Expression (5) or (6).

Next, in step S47, the immersion controller 23 controls the substrate holder 110 such that the substrates W in the lot 90 that is a processing target are lowered toward the processing liquid LQ in the processing tank 100.

Next, in step S48, the substrates W are processed with the processing liquid LQ in the processing tank 100 based on each corrected step period Uk.

Specifically, step S48 includes steps S481 to S485. Steps S481 to S485 are the same as steps S271 to S275 in FIG. 16, respectively. Hereinafter, differences will be mainly described.

First, in step S481, the immersion controller 23 starts the step period Uk according to the recipe information 32B.

Next, in step S482, the immersion controller 23 determines whether or not a replenishing timing of the chemical liquid has arrived.

In a case where it is determined in step S482 that a replenishing timing of the chemical liquid has not arrived (No), the processing proceeds to step S484.

On the other hand, in a case where it is determined in step S482 that the replenishing timing of the chemical liquid has arrived (Yes), the processing proceeds to step S483.

Next, in step S483, the immersion controller 23 controls the chemical liquid supplying portion 140 to replenish the processing tank 100 with the chemical liquid.

Next, in step S484, the immersion controller 23 determines whether or not an end timing of the ongoing step period UK has arrived.

In a case where it is determined in step S484 that the end timing of the step period Uk has not arrived (No), step S484 is repeated until the end timing arrives.

On the other hand, in a case where it is determined in step S484 that the end timing of the step period Uk has arrived (Yes), the processing proceeds to step S485.

Next, in step S485, the immersion controller 23 determines whether or not all of the step periods Uk constituting the processing time of the substrates W have ended.

In a case where it is determined in step S485 that all of the step periods Uk have not ended (No), the processing proceeds to step S481.

On the other hand, in a case where it is determined in step S485 that all of the step periods have ended (Yes), the processing proceeds to step S49.

Next, in step S49, the substrate holder 110 pulls up the substrates W from the processing liquid LQ in the processing tank 100. This point is the same as step S28 in FIG. 16. Then, the substrate processing method ends.

The preferred embodiments (including the modification examples) of the present invention have been described above with reference to the drawings. However, the present invention is not limited to the preferred embodiments described above and can be implemented in various modes within a scope not deviating from its gist. Also, it is possible to modify, as appropriate, the plurality of constituent elements disclosed in the preferred embodiments described above. For example, a certain constituent element among all constituent elements of a certain preferred embodiment may be added to the constituent elements of another preferred embodiment or some constituent elements among all constituent elements of a certain preferred embodiment may be deleted from the preferred embodiment.

Also, the drawings mainly illustrate the respective constituent elements schematically for ease of understanding of the invention and there are cases where thicknesses, lengths, numbers, intervals, etc., of the respective constituent elements illustrated differ from actuality due to convenience of drawing preparation. Also, the arrangements of the respective constituent elements indicated in the preferred embodiments described above are but an example, are not restricted in particular, and can obviously be changed variously within a scope of practically not deviating from the effects of the present invention.

(1) In preferred embodiment 1 (including the modification examples) and preferred embodiment 2 described with reference to FIGS. 1 to 19, the four items of relationship information 411 to 414 and the four reference points P1 to P4 have been described as preferable examples. However, each of the number of items of relationship information 41n and the number of reference points Pn is not particularly limited as long as it is two or more. For example, each of the number of items of relationship information 41n and the number of reference points Pn is preferably an integer of 2 or more and “N/2” or less when the maximum number of substrates W in one lot is “N.” This is to prevent complication of processing.

(2) In preferred embodiment 1 (including the modification examples) and preferred embodiment 2 described with reference to FIGS. 1 to 19, the processing time or the step period after the correction is calculated by subtracting the correction value based on the relationship information 41n from the processing time for the maximum number N of substrates W based on the processing time or the step period for the maximum number N of substrates W (refer to Expressions (1), (4), and (5)). However, the correction method is not limited thereto. For example, the processing time or the step period after correction may be calculated by adding a correction value based on the relationship information 41n to the processing time for the minimum number of substrates W, based on the processing time or the step period for the minimum number of substrates W (=1). In this case, the relationship information 41n is set such that the correction value increases as the number of substrates W increases. Alternatively, for example, the processing time or the step period after correction may be calculated by subtracting or adding a correction value based on the relationship information 41n from or to the processing time for ½ of the maximum number N of the substrates W, based on the processing time or the step period for ½ of the maximum number N of substrates W.

(3) In preferred embodiment 1 (including the modification examples) described with reference to FIGS. 1 to 14(b), the recipe information 32 may include the tank-dependent information 58 shown in FIG. 18. In this case, the processing time indicated by the processing time information 55 of the recipe information 32 is corrected by the tank-dependent correction value indicated by the tank-dependent correction value information 59.

For example, the corrector 22 calculates a corrected processing time Ta by Expression (7). In Expression (7), “Tc” denotes the processing time (Expression (1)) after correction based on the relationship information 41n, and “R” denotes the tank-dependent correction value.

$$T a = T c + R \qquad ( 7 )$$

Also, in preferred embodiment 1 (including the modification examples) described with reference to FIGS. 1 to 14(b), the recipe information 32 may include the chemical liquid replenishing amount information 56 shown in FIG. 18. In this case, the immersion controller 23 calculates the total replenishing amount of the chemical liquid in the corrected processing time by multiplying a chemical liquid replenishing amount (ml/substrate) indicated by the chemical liquid replenishing amount information 56 by the number of substrates W indicated by the number-of-substrates information 312. Then, the immersion controller 23 controls the chemical liquid supplying portion 140 to replenish the processing tank 100, in the corrected processing time, with the chemical liquid of the calculated total replenishing amount. As a result, in the corrected processing time, the chemical liquid supplying portion 140 replenishes the processing tank 100 with the chemical liquid.

(4) The number of step periods Ak in FIGS. 15 and 18 is not limited to five, and may take any value of two or more. Also, in FIG. 17, the number of the plurality of processing tanks 100 is not limited to four, and may be two or more.

Although the preferred embodiment of the present invention has been described in detail, these are merely specific examples used to clarify the technical contents of the present invention, and the present invention should not be construed as limited to these specific examples, and the scope of the present invention is limited only by the accompanying claims.

What is claimed is:

1. A substrate processing method of processing substrates by immersing at least one substrate in a processing liquid for each lot in a processing tank that stores the processing liquid, the substrate processing method comprising:
acquiring number-of-substrates information indicating the number of the substrates included in the lot;
selecting relationship information in accordance with the number of the substrates indicated by the number-of-substrates information from a plurality of items of relationship information, each of which indicates a relationship between the number of the substrates and a correction value of a processing time of the substrates;
acquiring a correction value in accordance with the number of the substrates indicated by the number-of-substrates information from the selected relationship information;
correcting a processing time of the substrates based on the acquired correction value such that the processing time is shorter than a processing time adopted in a case where the number of the substrates in the lot is a maximum number; and
processing the substrate with the processing liquid in the processing tank based on the corrected processing time of the substrates.

2. The substrate processing method according to claim 1, wherein each of the plurality of items of relationship information is a function indicating a relationship between the number of the substrates and a correction value of the processing time of the substrates.

3. The substrate processing method according to claim 2, wherein
the plurality of items of relationship information are defined by a plurality of reference points different from each other,
the substrate processing method further comprises receiving an input of a plurality of items of reference point correction value information which respectively determine the plurality of reference points, and
the plurality of items of reference point correction value information indicate respective correction values of processing times of the substrates which determine the corresponding reference points.

4. The substrate processing method according to claim 1, further comprising receiving an input of number setting information for setting the number of the plurality of items of relationship information.

5. The substrate processing method according to claim 1, further comprising receiving an input of invalid setting information which invalidates a function of correcting the processing time of the substrates.

6. The substrate processing method according to claim 2, wherein
the plurality of items of relationship information are defined by a plurality of reference points different from each other,
the substrate processing method further comprises receiving an input of a plurality of items of reference point number-of-substrates information which respectively determine the plurality of reference points, and
the plurality of items of reference point number-of-substrates information indicate respective numbers of the substrates in one lot which determine the corresponding reference points.

7. The substrate processing method according to claim 1, wherein
in a case where the number of the substrates in the lot indicates the maximum number, a correction value of the processing time of the substrates is zero,
in each of the plurality of items of relationship information, the correction value of the processing time of the substrates increases as the number of the substrates decreases, and
in correcting the processing time, the processing time of the substrates is corrected by subtracting the correction value in accordance with the number of the substrates indicated by the number-of-substrates information from the processing time of the substrates adopted in a case where the number of the substrates in the lot indicates the maximum number.

8. The substrate processing method according to claim 1, wherein
in acquiring the correction value, the correction value is set in accordance with disposition of the substrates in the processing tank, and
in correcting the processing time, the processing time of the substrates is corrected based on the set correction value.

9. The substrate processing method according to claim 8, wherein
in acquiring the correction value, in a case where the substrates are disposed in a first disposition state in the processing tank, a correction value of a processing time of the substrates disposed in the first disposition state is set such that a corrected processing time of the substrates is shorter than a corrected processing time of the substrates disposed in a reference disposition state,
the reference disposition state is a state in which the substrates are continuously disposed at equal intervals in a predetermined direction in the processing tank and are disposed in a region including a central portion of a substrate disposition maximum region in the predetermined direction, an interval between the adjacent substrates indicating a first distance,
the substrate disposition maximum region indicates a region where the substrates are disposed in a case where the number of the substrates in the lot is the maximum number, and
the first disposition state is a state in which the substrates are disposed at equal intervals in the predetermined direction in the processing tank, and an interval between the adjacent substrates indicates a second distance longer than the first distance.

10. The substrate processing method according to claim 8, wherein
in acquiring the correction value, in a case where the substrates are disposed in a second disposition state in the processing tank, a correction value of a processing time of the substrates disposed in the second disposition state is set such that a corrected processing time of the substrates is longer than a corrected processing time of the substrates disposed in a reference disposition state,
the reference disposition state is a state in which the substrates are continuously disposed at equal intervals in a predetermined direction in the processing tank and are disposed in a region including a central portion of a substrate disposition maximum region in the predetermined direction, an interval between the adjacent substrates indicating a first distance,
the substrate disposition maximum region indicates a region where the substrates are disposed in a case where the number of the substrates in the lot is the maximum number,
the second disposition state is a state in which the plurality of substrates in the lot are divided into a first substrate group and a second substrate group and are disposed in the processing tank,
the first substrate group and the second substrate group are not disposed in a central portion of the substrate disposition maximum region,
the first substrate group is disposed in an end region on one side of the substrate disposition maximum region in the predetermined direction,
the second substrate group is disposed in an end region on the other side of the substrate disposition maximum region in the predetermined direction, and
in each of the first substrate group and the second substrate group, two or more of the substrates are disposed at equal intervals in the predetermined direction, and an interval between the adjacent substrates indicates the first distance.

11. The substrate processing method according to claim 8, wherein
in acquiring the correction value, in a case where the substrates are disposed in a third disposition state in the processing tank, a correction value of a processing time of the substrates disposed in the third disposition state is set such that a corrected processing time of the substrates is longer than a corrected processing time of the substrates disposed in a reference disposition state,
the reference disposition state is a state in which the substrates are continuously disposed at equal intervals in a predetermined direction in the processing tank and are disposed in a region including a central portion of a substrate disposition maximum region in the predetermined direction, an interval between the adjacent substrates indicating a first distance,
the substrate disposition maximum region indicates a region where the substrates are disposed in a case where the number of the substrates in the lot is the maximum number,
the third disposition state is a state in which the plurality of substrates in the lot are disposed in either a first substrate group or a second substrate group in the processing tank,
the first substrate group and the second substrate group are not disposed in the central portion of the substrate disposition maximum region,
the first substrate group is disposed in an end region on the one side of the substrate disposition maximum region in the predetermined direction,
the second substrate group is disposed in an end region on the other side of the substrate disposition maximum region in the predetermined direction, and
in each of the first substrate group and the second substrate group, two or more of the substrates are disposed at equal intervals in the predetermined direction, and an interval between the adjacent substrates indicates the first distance.

12. The substrate processing method according to claim 1, wherein
the processing time of the substrates before correction is divided into a plurality of step periods,
in correcting the processing time, of the plurality of step periods, a step period set as a period in which a chemical liquid is replenished is corrected based on the acquired correction value, and
in processing the substrates, the chemical liquid is replenished to the processing tank in the corrected step period.

13. The substrate processing method according to claim 12, wherein, in correcting the processing time, two or more step periods are corrected by equally distributing or proportionally distributing the acquired correction value to the two or more step periods in which the chemical liquid is replenished.

14. The substrate processing method according to claim 1, wherein
a plurality of the lots are processed in a plurality of the processing tanks, respectively,
a plurality of tank-dependent correction values are assigned to the plurality of processing tanks, respectively,
the tank-dependent correction values indicate correction values for correcting processing times of the substrates in accordance with processing characteristics of the corresponding processing tanks, and
in correcting the processing time, the processing times of the substrates is corrected based on the acquired correction values and the tank-dependent correction values.

15. A substrate processing apparatus that processes at least one substrate with a processing liquid for each lot, the substrate processing apparatus comprising:
a processing tank to store the processing liquid;
a substrate holder to hold the substrates and immerse the substrates in the processing liquid;
a storage to store number-of-substrates information indicating the number of the substrates included in the lot;
a selector to select relationship information in accordance with the number of the substrates indicated by the number-of-substrates information from a plurality of items of relationship information, each of which indicates a relationship between the number of the substrates and a correction value of a processing time of the substrates;
a corrector to acquire a correction value in accordance with the number of the substrates indicated by the number-of-substrates information from the selected relationship information, and to correct the processing time of the substrates based on the correction value such that the processing time is shorter than a processing time adopted in a case where the number of the substrates in the lot is the maximum number; and
an immersion controller to control the substrate holder such that the substrates are immersed in the processing liquid in accordance with the corrected processing time of the substrates.

16. A non-transitory computer-readable storage medium storing a computer program to be executed by a computer, wherein the computer program causes the computer to execute computing in accordance with the substrate processing method according to claim 1.
